(19) United States
(12) Patent Application Publication
(10) Pub. No.: US 2018/0323181 A1
(43) Pub. Date: Nov. 8, 2018

(54) LIGHT-EMITTING APPARATUS AND FABRICATING METHOD THEREOF

(71) Applicant: Au Optronics Corporation, Hsinchu (TW)

(72) Inventors: Tsung-Tien Wu, Hsinchu County (TW); Ho-Cheng Lee, Kaohsiung City (TW)

(73) Assignee: Au Optronics Corporation, Hsinchu (TW)

(21) Appl. No.: 16/034,361

(22) Filed: Jul. 13, 2018

Related U.S. Application Data
(62) Division of application No. 15/213,406, filed on Jul. 19, 2016.

(30) Foreign Application Priority Data
Apr. 11, 2016 (TW) 105111254

(51) Int. Cl. H01L 25/00; H01L 33/00; H01L 25/075

(52) U.S. Cl. CPC H01L 25/50; H01L 33/0095; H01L 25/0753

(57) ABSTRACT

A fabricating method of a light-emitting apparatus including the following steps is provided. An adhesive layer having first adhesive bump groups including first adhesive bumps is provided. A transfer stamp picks up first light-emitting device groups including first light-emitting devices. The transfer stamp approaches the adhesive layer such that the first light-emitting devices of one first light-emitting device group are in contact with the first adhesive bumps of one corresponding first adhesive bump group. When the first light-emitting devices are in contact with the first adhesive bumps, the remaining first light-emitting devices on the transfer stamp are staggered with the first adhesive bumps and are not in contact with the adhesive layer. The transfer stamp is kept away from the adhesive layer such that the first light-emitting devices stay on the first adhesive bumps of the corresponding first adhesive bump group.

### CROSS-REFERENCE TO RELATED APPLICATION

This application is a divisional application of U.S. application Ser. No. 15/213,406, filed on Jul. 19, 2016, now pending. The prior application Ser. No. 15/213,406 claims the priority benefit of Taiwan application serial no. 105111254, filed on Apr. 11, 2016. The entirety of each of the above-mentioned patent applications is hereby incorporated by reference herein and made a part of this specification.

### BACKGROUND OF THE INVENTION

### Field of the Invention

The invention relates to an electronic apparatus and a fabricating method thereof, and more particularly, to a light-emitting apparatus and a fabricating method thereof.

### Description of Related Art

The transfer micro-device technique is applied in the process of new electronic apparatuses. In the case of the process of a light-emitting apparatus, the process of the light-emitting apparatus includes the following steps: provide a transfer stamp having a plurality of transfer blocks; provide one light-emitting array, wherein the light-emitting array includes a plurality of target light-emitting devices and a plurality of non-target light-emitting devices interspersed between the plurality of target light-emitting devices; bring the transfer blocks of the transfer stamp in contact with the target light-emitting devices to pick up the plurality of desired light-emitting devices; transfer the target light-emitting devices onto a flat adhesive layer of a receiving substrate using the transfer stamp; and fabricate other structures carrying a plurality of light-emitting devices on the receiving substrate to complete an ultra-thin light-emitting apparatus. However, during the process in which the transfer stamp picks up the target light-emitting devices, the region between two adjacent transfer blocks of the transfer stamp is readily in contact with the non-target light-emitting devices due to compression and deformation, such that the non-target light-emitting devices are transferred onto the flat adhesive layer of the receiving substrate by mistake. Therefore, the process yield of the light-emitting apparatus is not high.

### SUMMARY OF THE INVENTION

The invention provides a light-emitting apparatus and a fabricating method thereof. The process yield thereof is high.

The fabricating method of a light-emitting apparatus of the invention includes the following steps (a) to (e). Step (a): a substrate and an adhesive layer covering the substrate are provided, wherein the adhesive layer has a plurality of first adhesive bump groups, and each of the first adhesive bump groups includes a plurality of first adhesive bumps. Step (b): a transfer stamp picks up a plurality of first light-emitting device groups, wherein each of the first light-emitting device groups includes a plurality of first light-emitting devices. Step (c): the transfer stamp approaches the adhesive layer such that the plurality of first light-emitting devices of one first light-emitting device group are in contact with the plurality of first adhesive bumps of one corresponding first adhesive bump group, wherein when the plurality of first light-emitting devices of the first light-emitting device group are in contact with the plurality of first adhesive bumps of the first adhesive bump groups, if the remaining first light-emitting device groups are on the transfer stamp, then the plurality of first light-emitting devices of the remaining first light-emitting device groups are staggered with the plurality of first adhesive bumps of the plurality of first adhesive bump groups and are not in contact with the adhesive layer. Step (d): the transfer stamp is kept away from the adhesive layer such that the plurality of first light-emitting devices of one of the first light-emitting device groups respectively stays on the plurality of first adhesive bumps of one corresponding first adhesive bump group. Step (e): steps (c) to (d) are repeated at least once such that the plurality of first light-emitting devices of the remaining first light-emitting device groups stays on the plurality of first adhesive bumps of the corresponding first adhesive bump group.

The light-emitting apparatus of the invention includes a substrate, an adhesive layer, a plurality of first light-emitting devices, and a plurality of second light-emitting devices. The adhesive layer covers the substrate and has a plurality of first adhesive bumps. The plurality of first light-emitting devices is respectively disposed on the plurality of first adhesive bumps of the adhesive layer. The plurality of second light-emitting devices is disposed on the substrate and staggered with the first adhesive bumps. The minimum distance of each of the first light-emitting devices and the substrate is greater than the minimum distance of each of the second light-emitting devices and the substrate.

In an embodiment of the invention, when the plurality of first light-emitting devices of the one first light-emitting device group is in contact with the plurality of first adhesive bumps of one corresponding first adhesive bump group, the plurality of first light-emitting devices of the remaining first light-emitting device groups is distributed between the plurality of first light-emitting devices of one first light-emitting device group in contact with the plurality of first adhesive bumps.

In an embodiment of the invention, the adhesive layer further has a plurality of second adhesive bump groups. Each of the second adhesive bump groups includes a plurality of second adhesive bumps. The height of each of the first adhesive bumps is greater than the height of each of the second adhesive bumps. At least a portion of a plurality of second adhesive bumps of the second adhesive bump groups is interspersed between the plurality of first adhesive bumps of the first adhesive bump groups. The fabricating method of the light-emitting apparatus further includes performing the following steps (f) to (i) after step (e). Step (f): the transfer stamp picks up a plurality of second light-emitting device groups, wherein each of the second light-emitting device groups includes a plurality of second light-emitting devices. Step (g): the transfer stamp approaches the adhesive layer such that the plurality of second light-emitting devices of one second light-emitting device group are in contact with the plurality of second adhesive bumps of one corresponding second adhesive bump group, wherein when the plurality of second light-emitting devices of one second light-emitting device group are in contact with the plurality of second adhesive bumps of one second adhesive bump group, if remaining second light-emitting device groups are on the transfer stamp, then the remaining second light-emitting device groups are staggered with the second adhesive bump groups and are not in contact with the adhesive layer. Step (h): the transfer stamp is kept away from the adhesive layer such that the plurality of second light-emitting devices of one second light-emitting device group respectively stay on the plurality of second adhesive bumps of one corresponding second adhesive bump group. Step (i): steps (g) to (h) are repeated at least once such that the plurality of second light-emitting devices of the remaining second light-emitting device groups stay on the plurality of second adhesive bumps of the corresponding second adhesive bump group.

In an embodiment of the invention, when the plurality of second light-emitting devices of the second light-emitting device groups is in contact with the plurality of second adhesive bumps of one second adhesive bump group, the plurality of second light-emitting devices of one of the plurality of remaining second light-emitting devices is in contact with the plurality of first light-emitting devices on the plurality of corresponding first adhesive bumps, and the plurality of first light-emitting devices prevents contact between the plurality of second light-emitting devices of one of the plurality of remaining second light-emitting devices and the adhesive layer. Another one of the plurality of remaining second light-emitting device groups is staggered with the first adhesive bumps and the second adhesive bumps and a gap is formed between the other one of the plurality of remaining second light-emitting device groups and the adhesive layer.

In an embodiment of the invention, the adhesive layer further has a plurality of third adhesive bump groups. Each of the third adhesive bump groups includes a plurality of third adhesive bumps. The height of each of the second adhesive bumps is greater than the height of each of the third adhesive bumps. At least a portion of a plurality of third adhesive bumps of the plurality of third adhesive bump groups is interspersed between the plurality of first adhesive bumps and the plurality of second adhesive bumps. The fabricating method of the light-emitting apparatus further includes performing the following steps (j) to (k) after step (i). Step (j): the transfer stamp picks up a plurality of third light-emitting device groups, wherein each of the third light-emitting device groups includes a plurality of third light-emitting devices. Step (k): the transfer stamp approaches the adhesive layer such that the plurality of third light-emitting devices of one third light-emitting device group are in contact with the plurality of corresponding third adhesive bumps, wherein when the plurality of third light-emitting devices of one third light-emitting device group are in contact with the plurality of third adhesive bumps of one third adhesive bump group, if remaining third light-emitting device groups are on the transfer stamp, then the remaining third light-emitting device groups are staggered with the third adhesive bump groups and are not in contact with the adhesive layer. Step (l): the transfer stamp is kept away from the adhesive layer such that the plurality of third light-emitting devices of one third light-emitting device group respectively stay on the plurality of third adhesive bumps of one corresponding third adhesive bump group. Step (m): steps (k) to (l) are repeated at least once such that the plurality of third light-emitting devices of the remaining third light-emitting device groups stay on the plurality of third adhesive bumps of the corresponding third adhesive bump group.

In an embodiment of the invention, when the plurality of third light-emitting devices of the one third light-emitting device group are in contact with the plurality of third adhesive bumps of one third adhesive bump group, one of the plurality of remaining third light-emitting device groups is in contact with the plurality of first light-emitting devices on the plurality of corresponding first adhesive bumps, and the plurality of first light-emitting devices prevent a contact between one of the plurality of remaining third light-emitting device groups and the adhesive layer, another one of the plurality of remaining third light-emitting device groups is in contact with the plurality of second light-emitting devices on the plurality of corresponding second adhesive bumps, and the plurality of second light-emitting devices prevent a contact between another one of the remaining plurality of third light-emitting device groups and the adhesive layer.

In an embodiment of the invention, the thickness of each of the third light-emitting devices is greater than the thickness of each of the second light-emitting devices, and the thickness of each of the second light-emitting devices is greater than the thickness of each of the first light-emitting devices.

In an embodiment of the invention, the light color of the first light-emitting devices, the light color of the second light-emitting devices, and the light color of the third light-emitting devices are different from one another.

In an embodiment of the invention, the light color of the first light-emitting devices, the light color of the second light-emitting devices, and the light color of the third light-emitting devices are selected from red, green, and blue.

In an embodiment of the invention, the adhesive layer further has a plurality of second adhesive bumps. The height of each of the first adhesive bumps is greater than the height of each of the second adhesive bumps. At least a portion of the second adhesive bumps is interspersed between the first adhesive bumps. The second light-emitting devices are respectively disposed on the second adhesive bumps of the adhesive layer.

In an embodiment of the invention, the adhesive layer further has a plurality of third adhesive bumps. The height of each of the second adhesive bumps is greater than the height of each of the third adhesive bumps. In particular, one third adhesive bump is located between one first adhesive bump and one second adhesive bump adjacent to each other. The light-emitting apparatus further includes a plurality of third light-emitting devices respectively disposed on the plurality of third adhesive bumps of the adhesive layer.

Based on the above, in the fabricating method of a light-emitting apparatus of an embodiment of the invention, the transfer stamp carrying a plurality of first light-emitting devices approaches the adhesive layer such that a portion of the first light-emitting devices picked up by the transfer stamp are in contact with a plurality of corresponding first adhesive bumps. Meanwhile, the remaining first light-emitting devices not to be transferred are staggered with the first adhesive bumps and are not easy to be in contact with the adhesive layer. Accordingly, the probability that the transfer stamp leaves the first light-emitting devices not to be transferred on the adhesive layer is significantly reduced, and therefore the process yield of the light-emitting apparatus is increased.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1U are cross-sectional schematics of a fabricating method of a light-emitting apparatus of an embodiment of the invention.

FIG. 2A to FIG. 2U are cross-sectional schematics of a fabricating method of a light-emitting apparatus of another embodiment of the invention.

### DESCRIPTION OF THE EMBODIMENTS

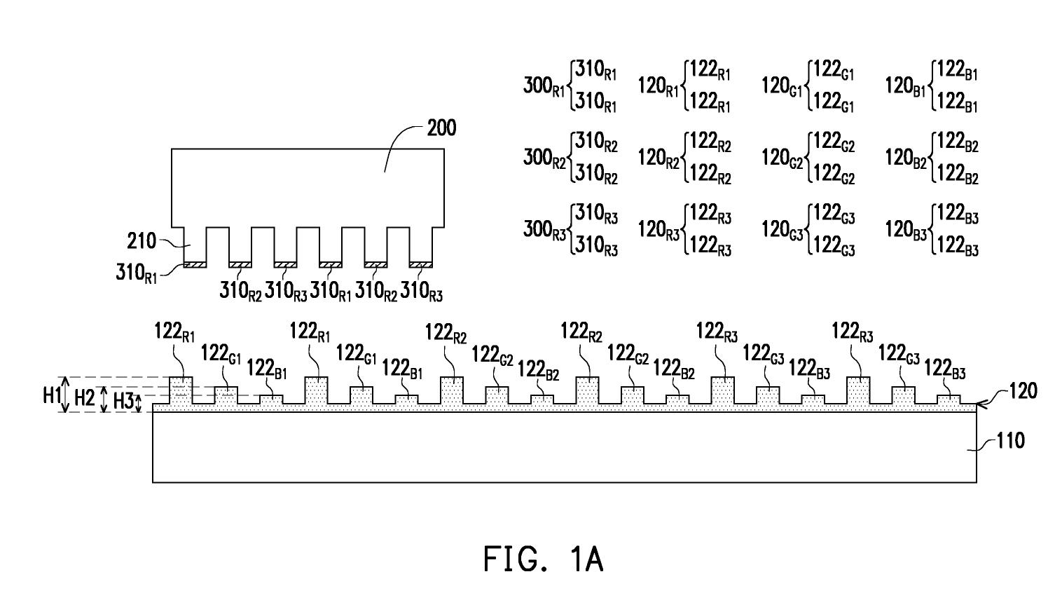

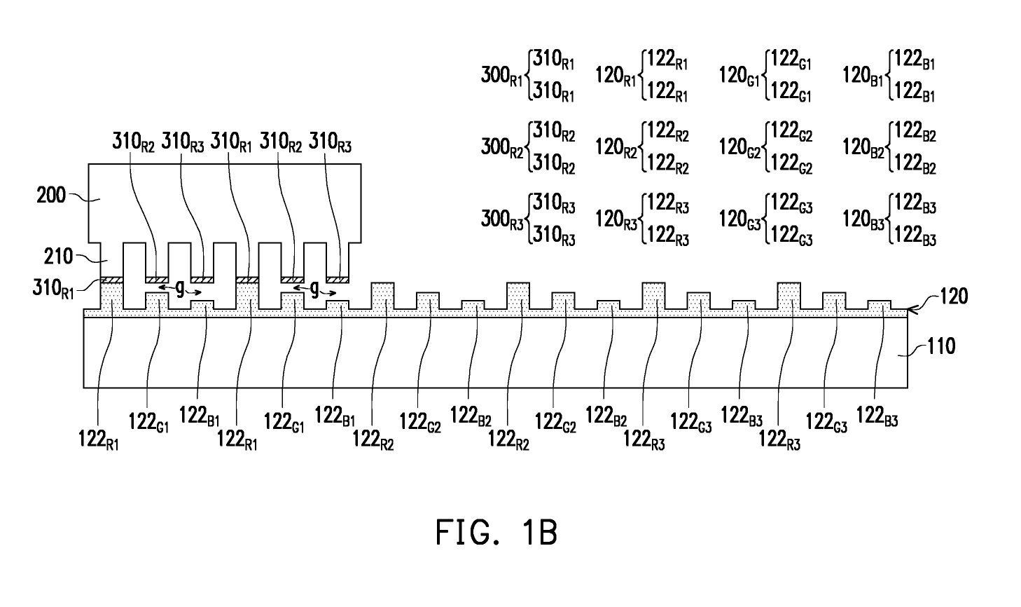

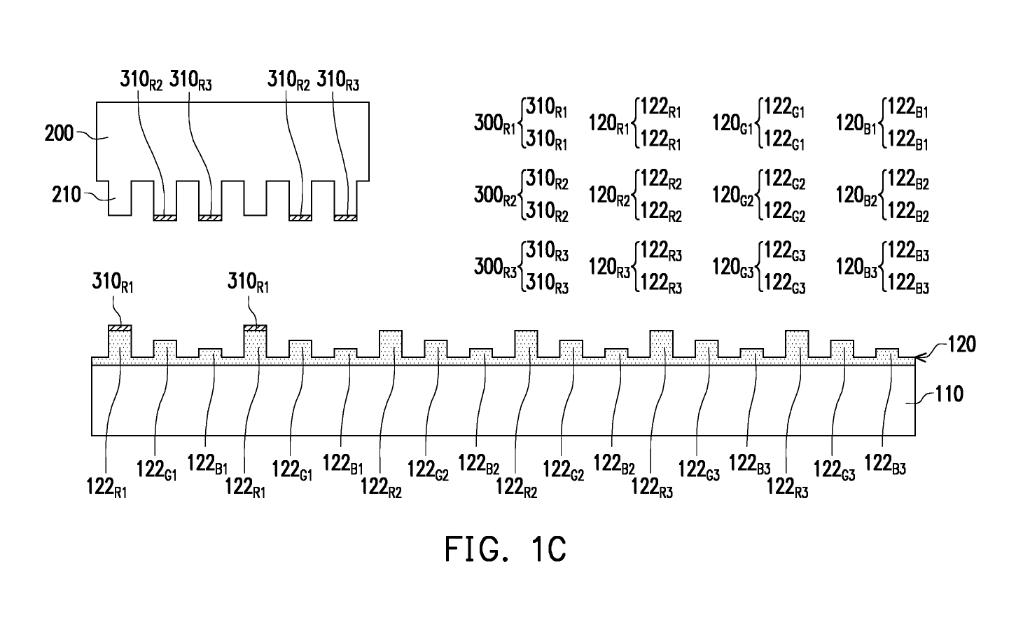

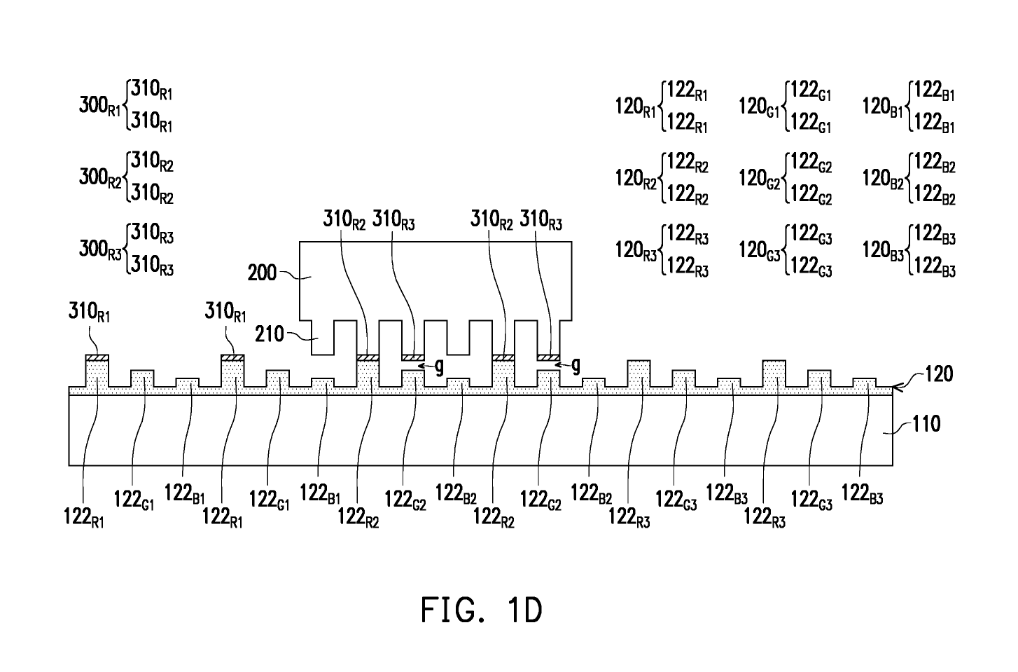

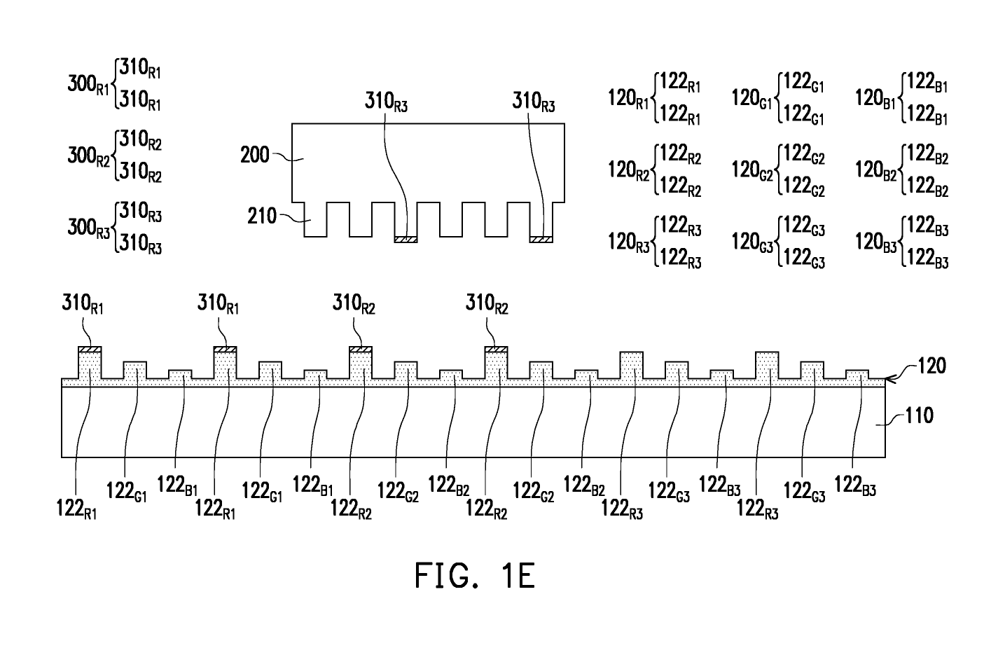

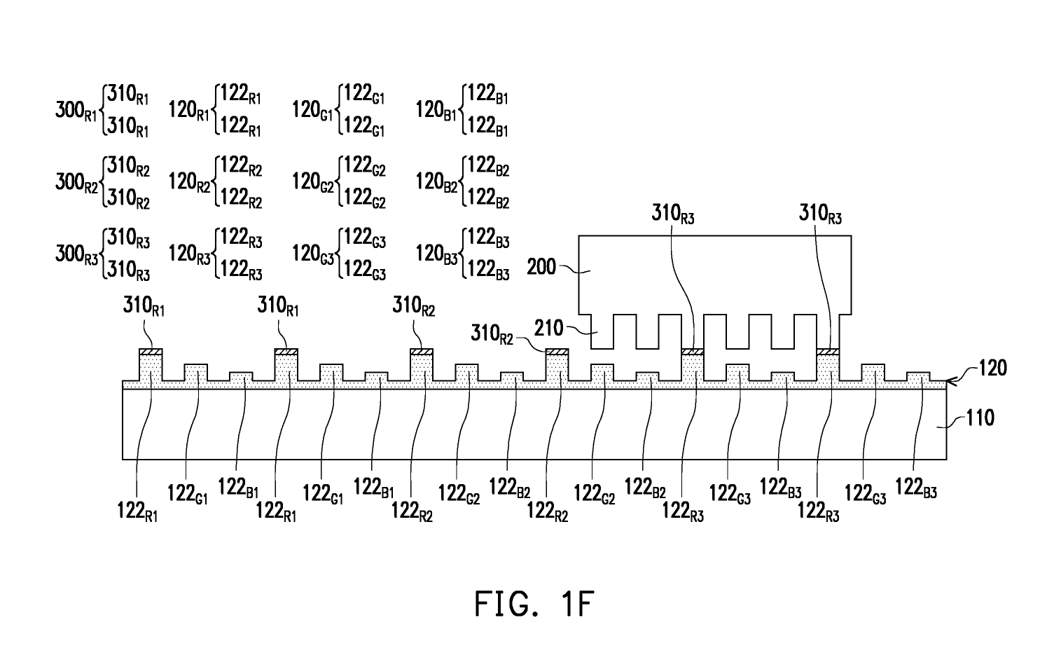

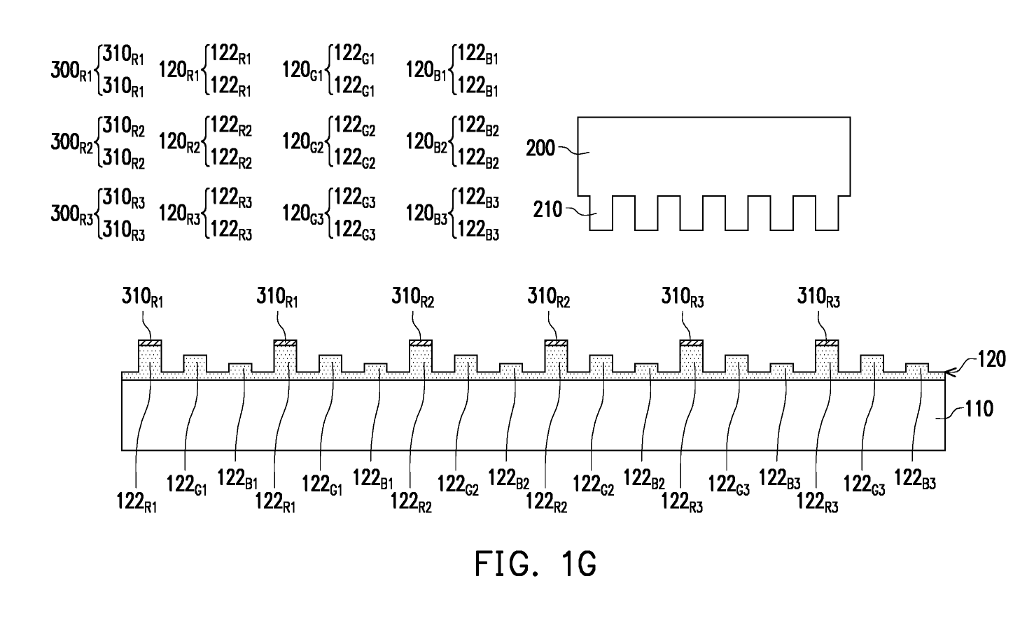

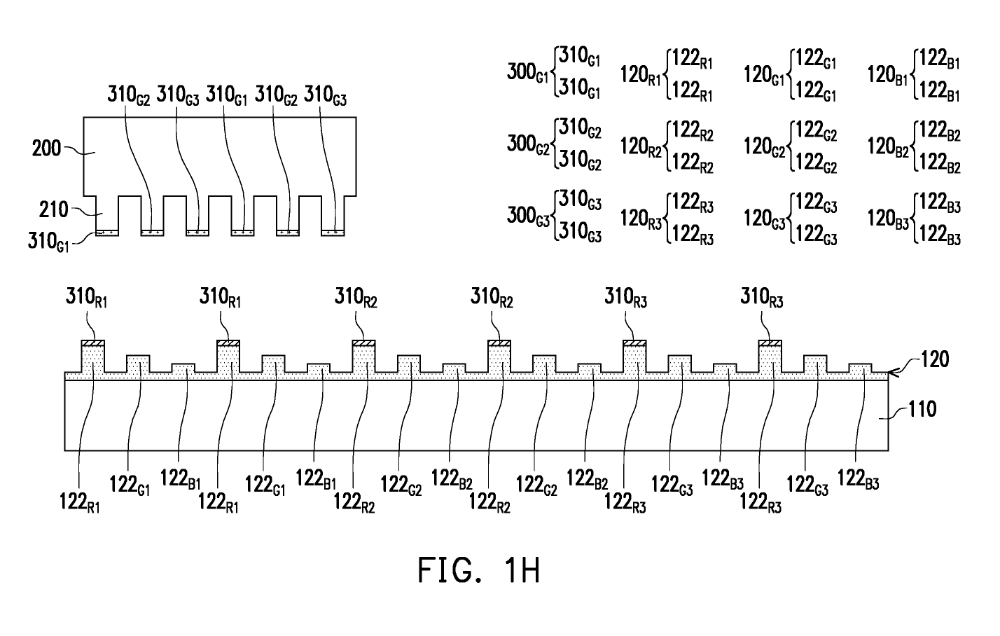

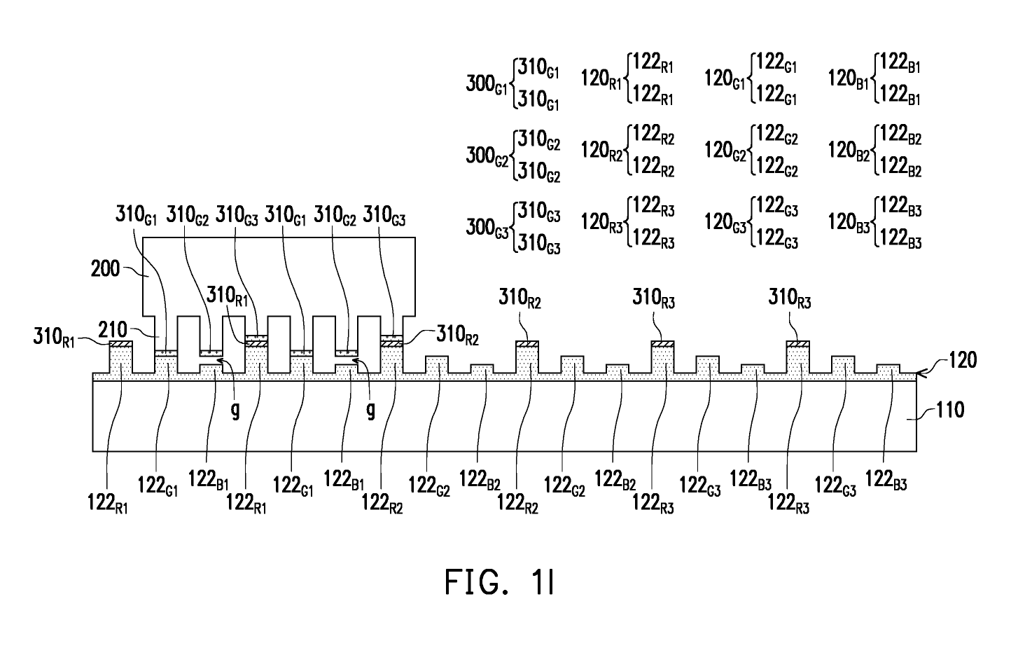

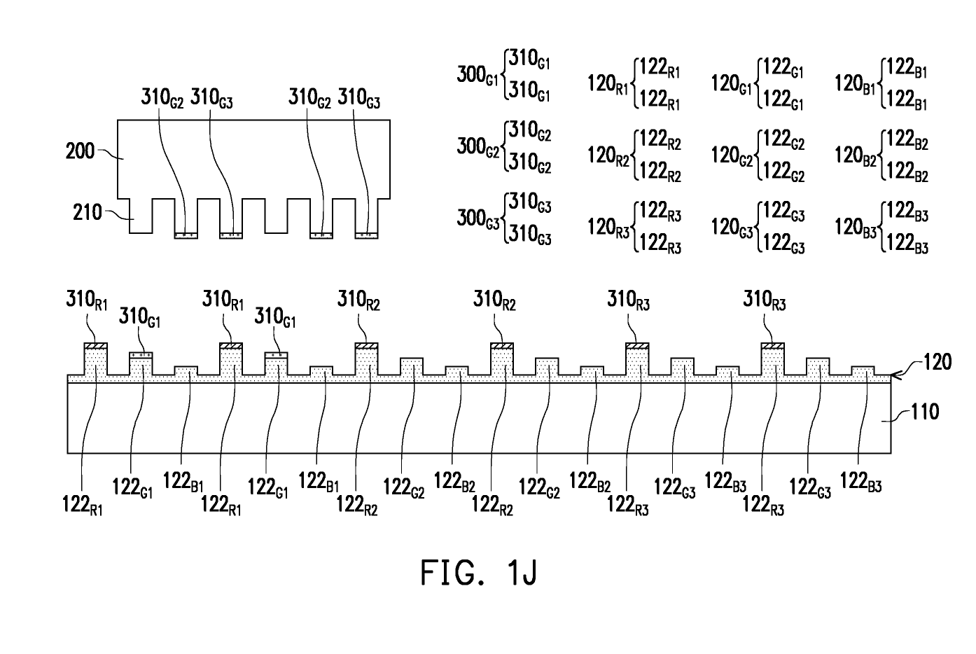

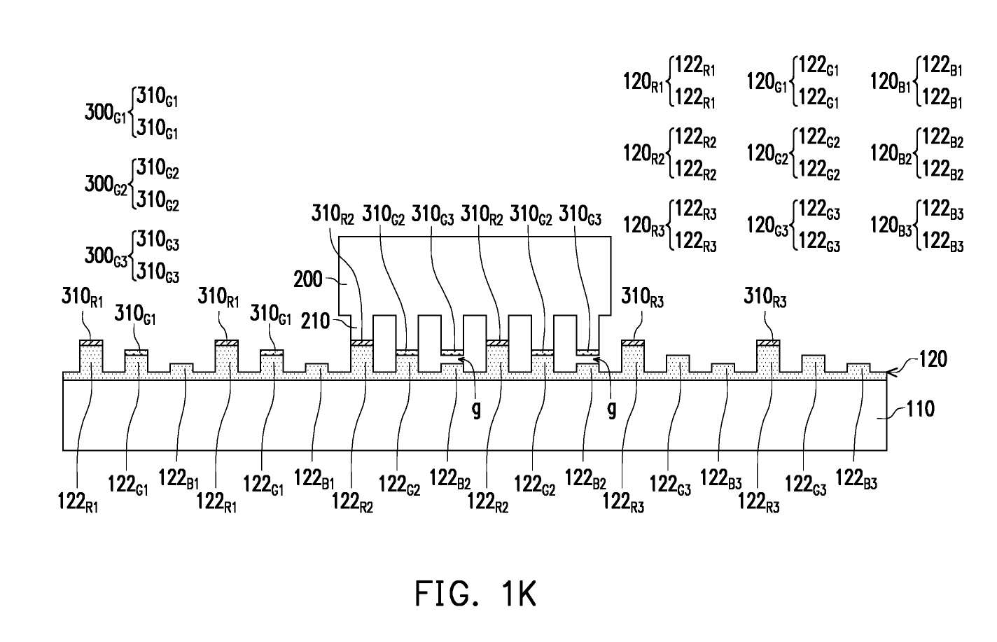

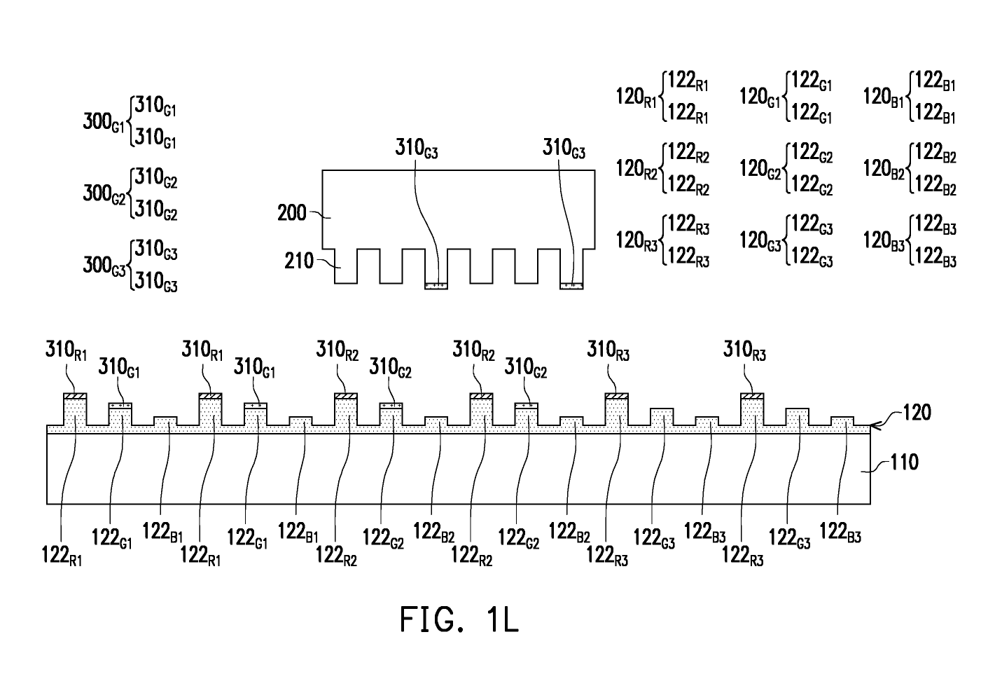

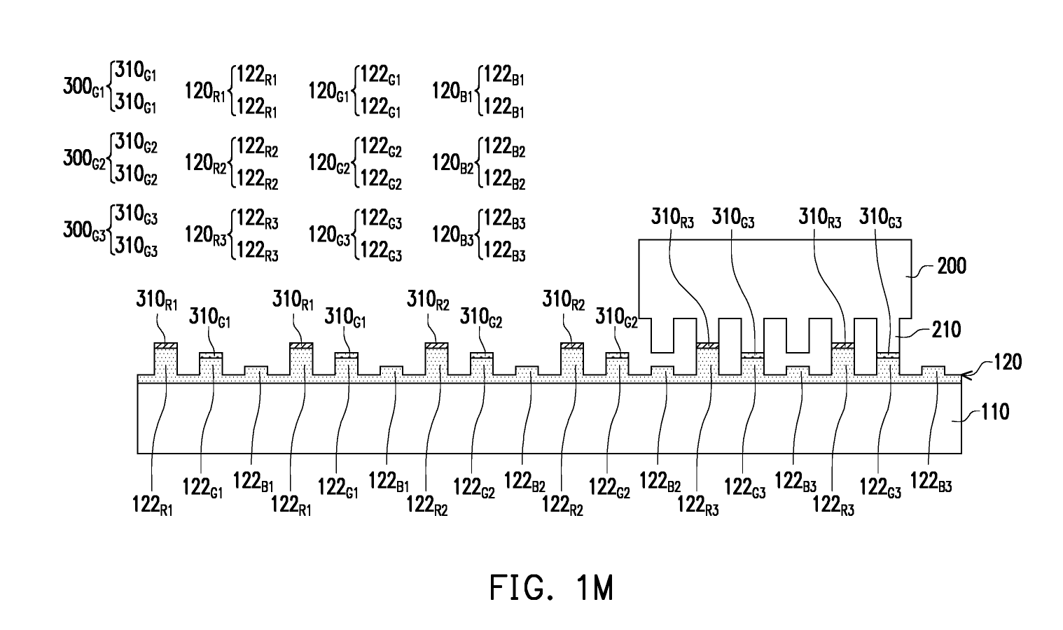

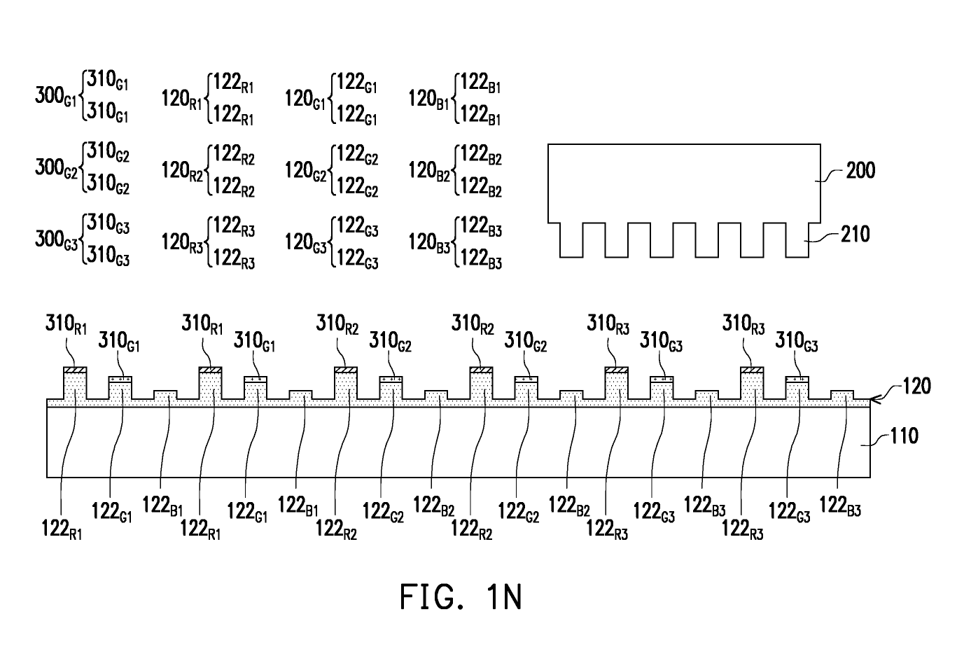

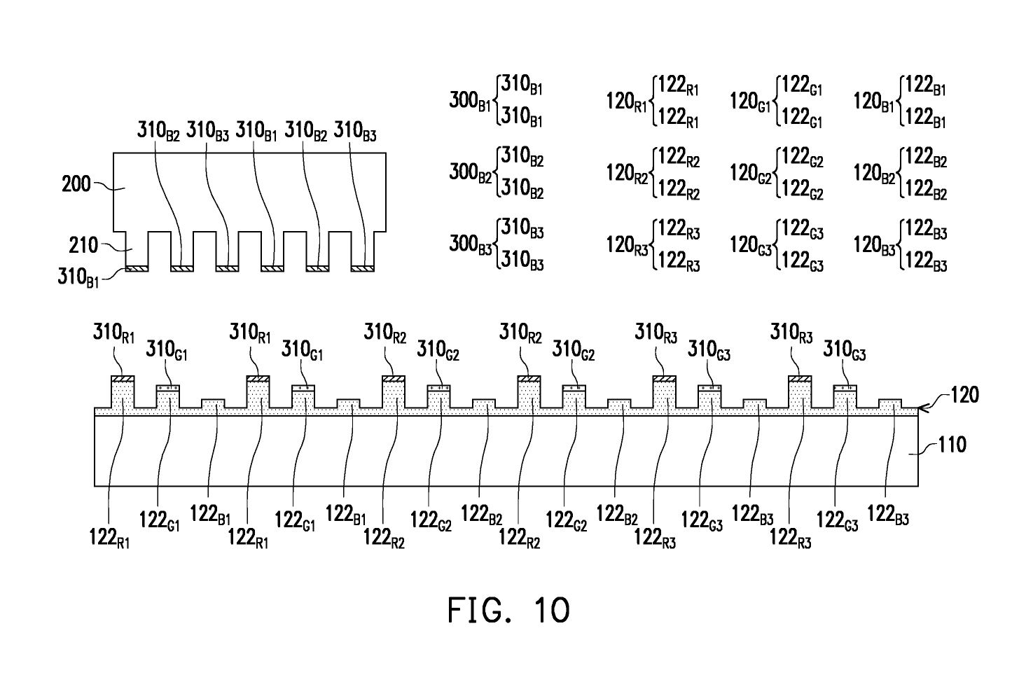

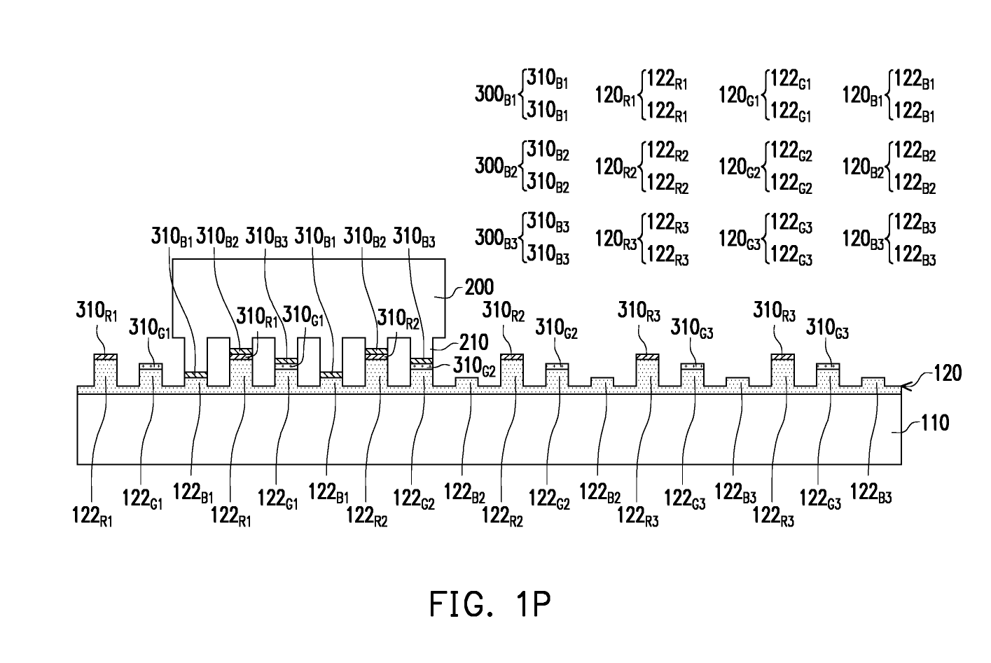

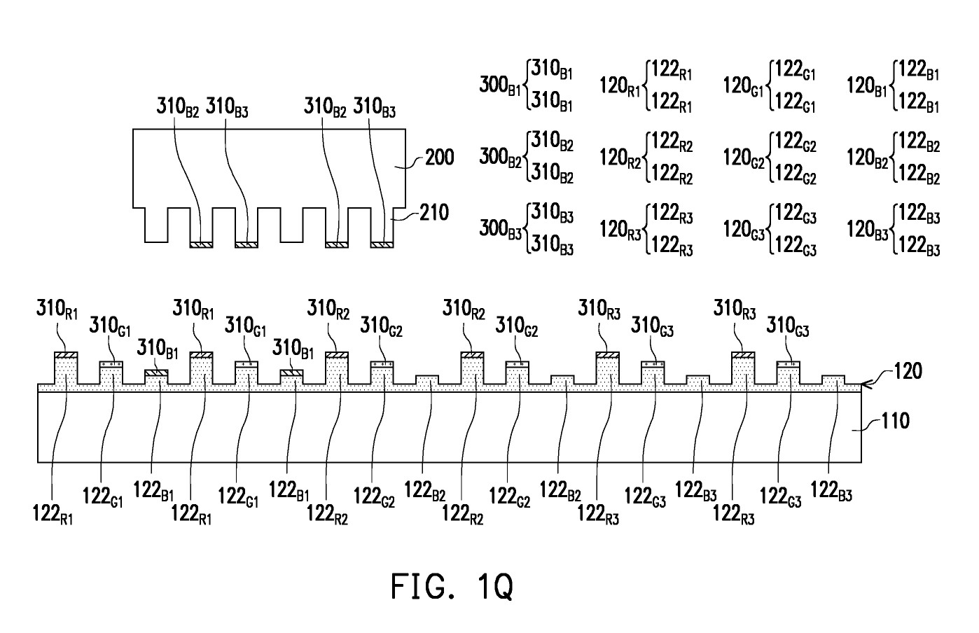

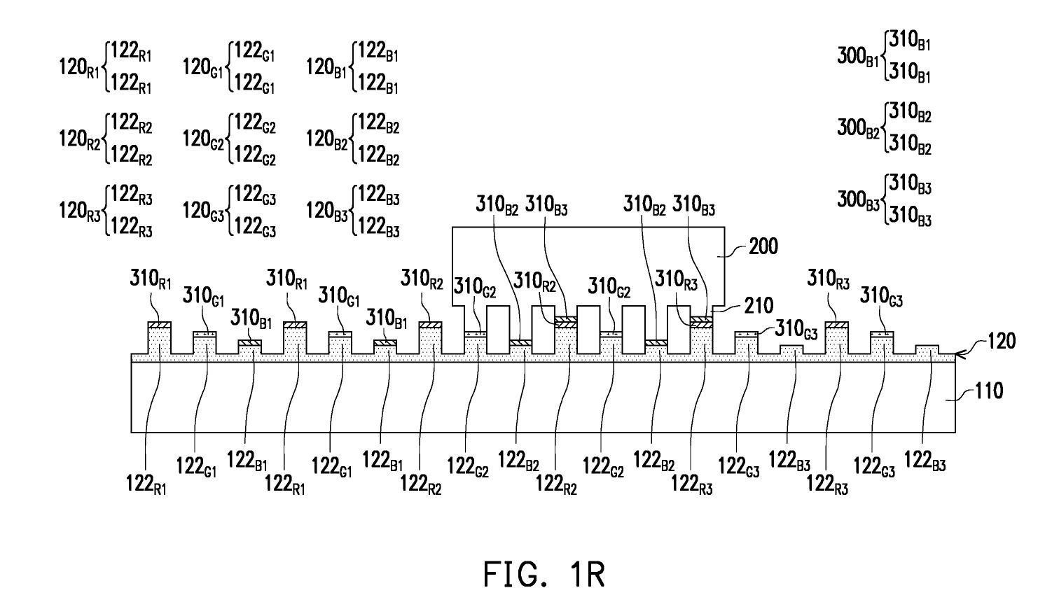

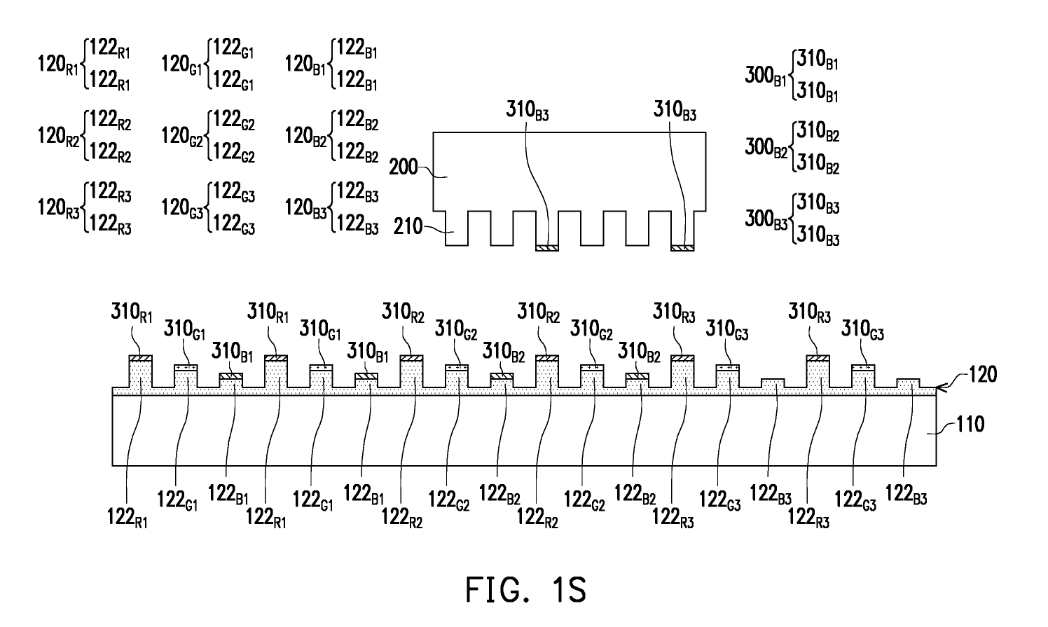

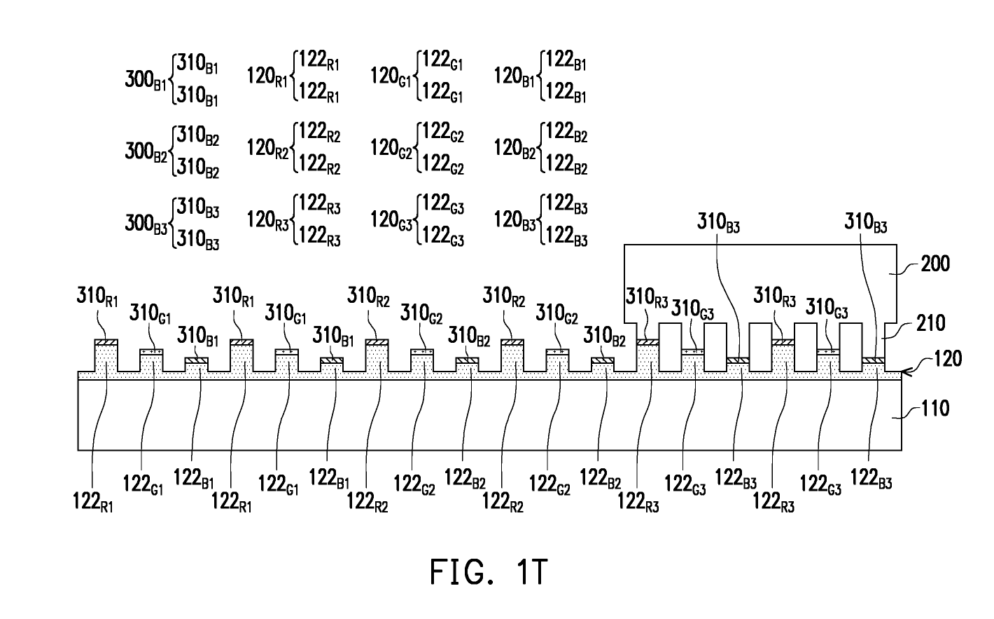

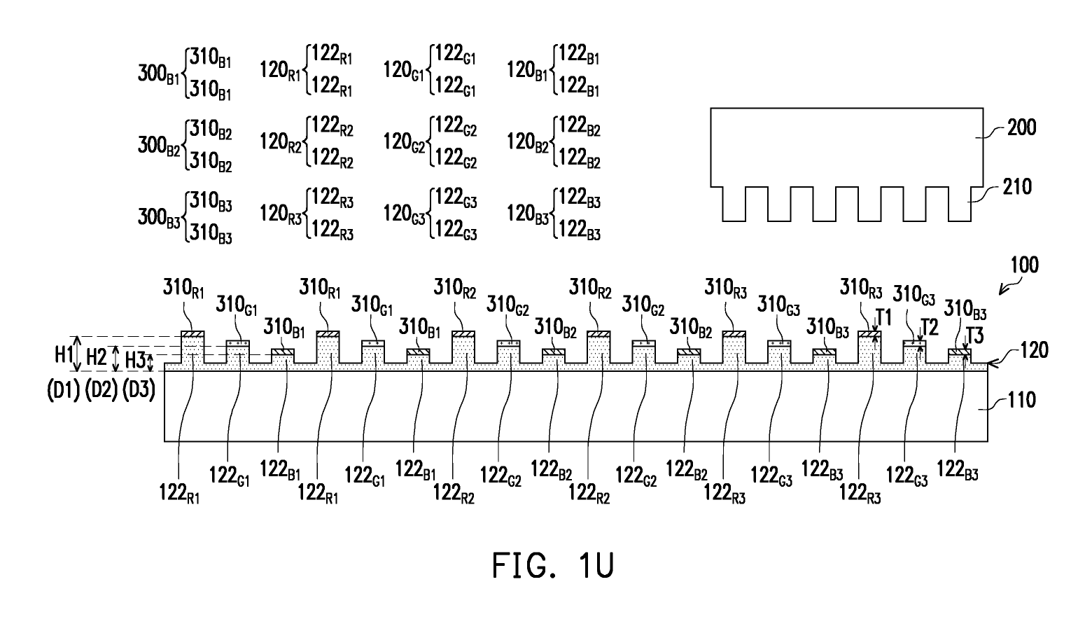

FIG. 1A to FIG. 1U are cross-sectional schematics of a fabricating method of a light-emitting apparatus of an embodiment of the invention. Referring first to FIG. 1A, first, step (a) is performed: a substrate 110 and an adhesive layer 120 covering the substrate 110 are provided. The adhesive layer 120 has a plurality of first adhesive bump groups 120_{R1}, 120_{R2}, and 120_{R3}. The first adhesive bump group 120_{R1} (120_{R2} or 120_{R3}) includes a plurality of first adhesive bumps 122_{R1} (122_{R2} or 122_{R3}). In the present embodiment, the adhesive layer 120 further has a plurality of second adhesive bump groups 120_{G1}, 120_{G2}, and 120_{G3}. The second adhesive bump group 120_{G1} (120_{G2} or 120_{G3}) includes a plurality of second adhesive bumps 122_{G1} (122_{G2} or 122_{G3}). At least a portion of the second adhesive bumps 122_{G1}, 122_{G2}, and 122_{G3} is interspersed between the plurality of first adhesive bumps 122_{R1}, 122_{R2}, and 122_{R3}. The adhesive layer 120 further has a plurality of third adhesive bump groups 120_{B1}, 120_{B2}, and 120_{B3}. The third adhesive bump group 120_{B1} (120_{B2} or 120_{B3}) includes a plurality of third adhesive bumps 122_{B1} (122_{B2} or 122_{B3}). At least a portion of the third adhesive bumps 122_{B1}, 122_{B2}, and 122_{B3} is interspersed between the plurality of first adhesive bumps 122_{R1}, 122_{R2}, and 122_{R3} and the plurality of second adhesive bumps 122_{G1}, 122_{G2}, and 122_{G3}. In particular, a height H1 of the first adhesive bumps 122_{R1}, 122_{R2}, and 122_{R3}, a height H2 of the second adhesive bumps 122_{G1}, 122_{G2}, and 122_{G3}, and a height H3 of the third adhesive bumps 122_{B1}, 122_{B2}, and 122_{B3} are different from one another (i.e., H1≠H2≠H3). For instance, the height H1 of all of the first adhesive bumps 122_{R1}, 122_{R2}, and 122_{R3} is substantially the same, the height H2 of all of the second adhesive bumps 122_{G1}, 122_{G2}, and 122_{G3} is substantially the same, the height H3 of all of the third adhesive bumps 122_{B1}, 122_{B2}, and 122_{B3} is substantially the same, the height H1 of each of the first adhesive bumps 122_{R1}, 122_{R2}, and 122_{R3} can be greater than the height H2 of each of the second adhesive bumps 122_{G1}, 122_{G2}, and 122_{G3}, and the height H2 of each of the second adhesive bumps 122_{G1}, 122_{G2}, and 122_{G3} can be greater than the height H3 of each of the third adhesive bumps 122_{B1}, 122_{B2}, and 122_{B3}, but the invention is not limited thereto.

Referring to FIG. 1A, next, step (b) is performed: a transfer stamp 200 picks up a plurality of first light-emitting device groups 300_{R1}, 300_{R2}, and 300_{R3}. Each of the first light-emitting device groups 300_{R1} (300_{R2} or 300_{R3}) includes a plurality of first light-emitting devices 310_{R1} (310_{R2} or 310_{R3}). In the present embodiment, the transfer stamp 200 can have a plurality of transfer bumps 210. The plurality of transfer bumps 210 respectively picks up a plurality of first light-emitting devices 310_{R1}, 310_{R2}, and 300_{R3}. However, the invention is not limited thereto, and in other embodiments, the transfer stamp 200 may not have the plurality of transfer bumps 210, and a flat transfer surface (not shown) of the transfer stamp 200 may be used to pick up the plurality of first light-emitting devices 310_{R1}, 310_{R2}, and 310_{R3} at the same time. In the present embodiment, the first light-emitting devices 310_{R1}, 310_{R2}, or 310_{R3} are, for instance, red micro light-emitting diodes (micro-LED). In other words, the light color of the first light-emitting devices 310_{R1}, 310_{R2}, or 310_{R3} may be red, but the invention is not limited thereto.

Next, step (c) is performed: the transfer stamp approaches the adhesive layer such that the plurality of first light-emitting devices of one first light-emitting device group are in contact with the plurality of first adhesive bumps of one corresponding first adhesive bump group, wherein when the first light-emitting devices of the first light-emitting device group are in contact with the first adhesive bumps of the first adhesive bump group, if remaining first light-emitting device groups are on the transfer stamp, then the plurality of first light-emitting devices of the remaining first light-emitting device groups are staggered with the plurality of first adhesive bumps of the first adhesive bump groups and are not in contact with the adhesive layer. Specifically, as shown in FIG. 1B, the transfer stamp 200 approaches the adhesive layer 120 such that the plurality of first light-emitting devices 310_{R1} (i.e., target first light-emitting devices) of one first light-emitting device group 300_{R1} are in contact with the plurality of first adhesive bumps 122_{R1} of one corresponding first adhesive bump group 120_{R1}. When the first light-emitting devices 310_{R1} of the first light-emitting device group 300_{R1} are in contact with the first adhesive bumps 122_{R1} of the first adhesive bump group 120_{R1}, if remaining first light-emitting device groups 300_{R2} and 300_{R3} (i.e., non-target first light-emitting devices) are on the transfer stamp 200, then the plurality of first light-emitting devices 310_{R2} and 310_{R3} of the remaining first light-emitting device groups 300_{R2} and 300_{R3} are staggered with the plurality of first adhesive bumps 122_{R1}, 122_{R2}, and 122_{R3} of the first adhesive bump groups 120_{R1}, 120_{R2}, and 120_{R3} and are not in contact with the adhesive layer 120. In detail, when the first light ting devices 310_{R1} of the first light-emitting device group 300_{R1} are in contact with the first adhesive bumps 122_{R1} of the corresponding first adhesive bump group 120_{R1}, at least a portion of the remaining first light-emitting devices 310_{R1} and 310_{R3} are distributed between the plurality of first light-emitting devices 310_{R1} in contact with the first adhesive bumps 122_{R1}. Gaps g are formed between the remaining first light-emitting devices 310_{R2} and 310_{R3} and the second and third adhesive bumps 122_{G1} and 122_{B1} corresponding to the remaining first light-emitting devices 310_{R2} and 310_{R3}. For instance, a size of the gap g formed between the first light-emitting devices 310_{R2} and the second adhesive bumps 122_{G1} is different form a size of the gap g formed between the first light-emitting devices 310_{R3} and the third adhesive bumps 122_{B1}.

Next, step (d) is performed: the transfer stamp is kept away from the adhesive layer such that the plurality of first light-emitting devices of one first light-emitting device group respectively stay on the plurality of first adhesive bumps of the corresponding first adhesive bump group. Specifically, as shown in FIG. 1C, the transfer stamp 200 is formed away from the adhesive layer 120 such that the plurality of first light-emitting devices 310_{R1} of the first light-emitting device group 300_{R1} respectively stay on the plurality of first adhesive bumps 122_{R1} of the corresponding first adhesive bump group 120_{R1}. Meanwhile, the plurality of first light-emitting devices 310_{R2} and 310_{R3} (i.e., non-target first light-emitting devices) of the first light-emitting device groups 300_{R2} and 300_{R3} not in contact with the adhesive layer 120 are kept away from the adhesive layer 120 together with the transfer stamp 200 and does not stay on the adhesive layer 120.

Then, step (e) is performed: steps (c) to (d) are repeated at least once such that the plurality of first light-emitting devices of the remaining first light-emitting device groups stay on the plurality of first adhesive bumps of the corresponding first adhesive bump group. Specific description is as follows.

Referring to FIG. 1D, after the first light-emitting devices 310_{R1} respectively stay on the plurality of corresponding first adhesive bumps 122_{R1}, the transfer stamp 200 approaches the adhesive layer 120 such that the plurality of first light-emitting devices 310_{R2} of the first light-emitting device group 300_{R2} are in contact with the plurality of first adhesive bumps 122_{R2} of the corresponding first adhesive bump group 120_{R2}. When the first light-emitting devices 310_{R2} of the first light-emitting device group 300_{R2} are in contact with the first adhesive bumps 122_{R2} of the first adhesive bump group 120_{R2}, if remaining first light-emitting device groups 300_{R3} are on the transfer stamp 200, then the plurality of first light-emitting devices 310_{R3} of the remaining first light-emitting device groups 300_{R3} are staggered with the plurality of first adhesive bumps 122_{R1}, 122_{R2}, and 122_{R3} of the first adhesive bump groups 120_{R1}, 120_{R2}, and 120_{R3} and are not in contact with the adhesive layer 120. Specifically, when the first light-emitting devices 310_{R2} of the first light-emitting device group 300_{R2} are in contact with the first adhesive bumps 122_{R2} of the corresponding first adhesive bump group 120_{R2}, at least a portion of the remaining first light-emitting devices 310_{R3} is distributed between the plurality of first light-emitting devices 310_{R2} in contact with the first adhesive bumps 122_{R2}. A gap g is formed between the remaining first light-emitting devices 310_{R3} and the corresponding second adhesive bumps 122_{G2}.

As shown in FIG. 1E, next, the transfer stamp 200 is formed away from the adhesive layer 120 such that the plurality of first light-emitting devices 310_{R2} of the first light-emitting device group 300_{R2} respectively stay on the plurality of first adhesive bumps 122_{R2} of the corresponding first adhesive bump group 120_{R2}. Meanwhile, the plurality of first light-emitting devices 310_{R3} of the first light-emitting device group 300_{R3} not in contact with the adhesive layer 120e is kept away from the adhesive layer 120 together with the transfer stamp 200 and does not stay on the adhesive layer 120.

As shown in FIG. 1F, after the plurality of first light-emitting devices 310_{R1} and 310_{R2} respectively stay on the corresponding plurality of first adhesive bumps 122_{R1} and 122_{R2}, the transfer stamp 200 approaches the adhesive layer 120 such that the plurality of first light-emitting devices 310_{R3} of the first light-emitting device group 300_{R3} are in contact with the plurality of first adhesive bumps 122_{R3} of the corresponding first adhesive bump group 120_{R3}. As shown in FIG. 1G, next, the transfer stamp 200 is kept away from the adhesive layer 120 such that the plurality of first light-emitting devices 310_{R3} of the first light-emitting device group 300_{R3} respectively stay on the plurality of first adhesive bumps 122_{R2} of the corresponding first adhesive bump group 120_{R3}. Meanwhile, all of the first light-emitting devices 310_{R1}, 310_{R2}, and 310_{R3} are respectively transferred onto the corresponding first adhesive bumps 122_{R1}, 122_{R2}, and 122_{R3} by the transfer stamp 200.

Referring to FIG. 1H, next, step (f) is performed: the transfer stamp 200 picks up a plurality of second light-emitting device groups 300_{G1}, 300_{G2}, and 300_{G3}. Each of the second light-emitting device groups 300_{G1} (300_{G2} or 300_{G3}) includes a plurality of second light-emitting devices 310_{G1} (310_{G2} or 310_{G3}). In the present embodiment, the transfer stamp 200 can have a plurality of transfer bumps 210. The plurality of transfer bumps 210 respectively picks up the plurality of second light-emitting devices 310_{G1}, 310_{G2}, and 310_{G3}. However, the invention is not limited thereto, and in other embodiments, the transfer stamp 200 may not have the transfer bumps 210, and a flat transfer surface (not shown) of the transfer stamp 200 may be used to pick up the plurality of second light-emitting devices 310_{G1}, 310_{G2}, and 310_{G3} at the same time. The second light-emitting devices 310_{G1}, 310_{G2}, and 310_{G3} may be, for instance, green micro-LEDs. In other words, the light color of the second light-emitting devices 310_{G1}, 310_{G2}, and 310_{G3} may be green, but the invention is not limited thereto.

Next, step (g) is performed: the transfer stamp approaches the adhesive layer such that the plurality of second light-emitting devices of one second light-emitting device group are in contact with the plurality of second adhesive bumps of one corresponding second adhesive bump group, wherein when the second light-emitting devices of the second light-emitting device group are in contact with the second adhesive bumps of the second adhesive bump group, if remaining second light-emitting device groups are on the transfer stamp, then the plurality of second light-emitting devices of the remaining second light-emitting device groups are staggered with the plurality of second adhesive bumps of the second adhesive bump group and are not in contact with the adhesive layer. Specifically, as shown in FIG. 11, the transfer stamp 200 approaches the adhesive layer 120 such that the plurality of second light-emitting devices 310_{G1} of the second light-emitting device group 300_{G1} are in contact with the plurality of second adhesive bumps 122_{G1} of the corresponding second adhesive bump group 120_{G1}. When the second light-emitting devices 310_{G1} of the second light-emitting device group 300_{G1} are in contact with the second adhesive bumps 122_{G1} of the second adhesive bump group 120_{G1}, if remaining second light-emitting device groups 300_{G2} and 300_{G3} are on the transfer stamp 200, then the plurality of second light-emitting devices 310_{G2} and 310_{G3} of the remaining second light-emitting device groups 300_{G2} and 300_{G3} are staggered with the plurality of second adhesive bumps 122_{G1}, 122_{G2}, and 122_{G3} of the second adhesive bump groups 120_{G1}, 120_{G2}, and 120_{G3} and are not in contact with the adhesive layer 120. More specifically, when the second light-emitting devices 310_{G1} are in contact with the second adhesive bumps 122_{G1}, the plurality of second light-emitting devices 310_{G3} of the second light-emitting device group 300_{G3} are in contact with the plurality of first light-emitting devices 310_{R1} and 310_{G2} on the first adhesive bumps 122_{R1} and 122_{R2}, and the first light-emitting devices 310_{R1} and 310_{R2} prevent a contact between the second light-emitting devices 310_{G3} of the second light-emitting device group 300_{G3} and the adhesive layer 120. Moreover, the plurality of second light-emitting devices 310_{G2} of the second light-emitting device group 300_{G2} are staggered with the first adhesive bumps 122_{R1}, 122_{R2}, and 122_{R3} and the second adhesive bumps 122_{G1}, 122_{G2}, and 122_{G3} and the gap g is formed between the plurality of second light-emitting devices 310_{G2} of the second light-emitting device group 300_{G2} and the adhesive layer 120.

Next, step (h) is performed: the transfer stamp is kept away from the adhesive layer such that the plurality of second light-emitting devices of one second light-emitting device group respectively stay on the plurality of second adhesive bumps of the corresponding second adhesive bump group. Specifically, as shown in FIG. 1J, the transfer stamp 200 is kept away from the adhesive layer 120 such that the plurality of second light-emitting devices 310_{G1} of the second light-emitting device group 300_{G1} respectively stay on the plurality of second adhesive bumps 122_{G1} of the corresponding second adhesive bump group 120_{G1}. Meanwhile, the plurality of second light-emitting devices 310_{G2} and 310_{G3} of the second light-emitting device groups 310_{G2} and 310_{G3} not in contact with the adhesive layer 120 are kept away from the adhesive layer 120 together with the transfer stamp 200 and does not stay on the adhesive layer 120.

Then, step (i) is performed: steps (g) to (h) are repeated at least once such that the plurality of second light-emitting devices of the remaining second light-emitting device groups stay on the plurality of second adhesive bumps of the corresponding second adhesive bump group. Specific description is as follows.

Referring to FIG. 1K, next, the transfer stamp 200 approaches the adhesive layer 120 such that the plurality of second light-emitting devices 310_{G2} of the second light-emitting device group 300_{G2} are in contact with the plurality of second adhesive bumps 122_{G2} of the corresponding second adhesive bump group 120_{G2}. When the second light-emitting devices 310_{G2} of the second light-emitting device group 300_{G2} are in contact with the second adhesive bumps 122_{G2} of the second adhesive bump group 120_{G2}, if remaining second light-emitting device groups 300_{G3} are on the transfer stamp 200, then the plurality of second light-emitting devices 310_{G3} of the remaining second light-emitting device groups 300_{G3} are staggered with the plurality of second adhesive bumps 122_{G1}, 122_{G2}, and 122_{G3} of the second adhesive bump groups 120_{G1}, 120_{G2}, and 120_{G3} and are not in contact with the adhesive layer 120. More specifically, when the second light-emitting devices 310_{G2} are in contact with the second adhesive bumps 122_{G2}, the gap g is formed between the plurality of light-emitting devices 310_{G3} of the remaining second light-emitting device groups 300_{G3} and the corresponding third adhesive bumps 122_{B2}.

As shown in FIG. 1L, next, the transfer stamp 200 is formed away from the adhesive layer 120 such that the plurality of second light-emitting devices 310_{G2} of the second light-emitting device group 300_{G2} respectively stays on the plurality of second adhesive bumps 122_{G2} of the corresponding second adhesive bump group 120_{G2}. At this point, the plurality of second light-emitting devices 310_{G3} of the second light-emitting device group 300_{G3} not in contact with the adhesive layer 120 before is formed away from the adhesive layer 120 together with the transfer stamp 200 and does not stay on the adhesive layer 120.

As shown in FIG. 1M, next, the transfer stamp 200 approaches the adhesive layer 120 such that the plurality of second light-emitting devices 310_{G3} of the second light-emitting device group 300_{G3} are in contact with the plurality of second adhesive bumps 122_{G3} of the corresponding second adhesive bump group 120_{G3}. As shown in FIG. 1N, next, the transfer stamp 200 is kept away from the adhesive layer 120 such that the plurality of second light-emitting devices 310_{G3} of the second light-emitting device group 300_{G3} respectively stay on the plurality of second adhesive bumps 122_{G3} of the corresponding second adhesive bump group 120_{G3}. Meanwhile, all of the second light-emitting devices 310_{G1}, 310_{G2}, and 310_{G3} are respectively transferred onto the corresponding second adhesive bumps 122_{G1}, 122_{G1}, and 122_{G3} by the transfer stamp 200.

Referring to FIG. 1O, next, step (j) is performed: the transfer stamp 200 picks up a plurality of third light-emitting device groups 300_{B1}, 300_{B2}, and 300_{B3}. Each of the third light-emitting device groups 300_{B1} (300_{B2} or 300_{B3}) includes a plurality of third light-emitting devices 310_{B1} (310_{B2} or 310_{B3}). In the present embodiment, the transfer stamp 200 may have a plurality of transfer bumps 210. The plurality of transfer bumps 210 respectively picks up a plurality of third light-emitting devices 310_{B1}, 310_{B2}, and 310_{B3}. However, the invention is not limited thereto, and in other embodiments, the transfer stamp 200 may not have the transfer bumps 210, and a flat transfer surface (not shown) of the transfer stamp 200 may be used to pick up the plurality of third light-emitting devices 310_{G1}, 310_{G2}, and 310_{G3} at the same time. The third light-emitting devices 310_{G1}, 310_{G2}, or 310_{G3} may be, for instance, blue micro-LEDs. In other words, the light color of the third light-emitting devices 310_{G1}, 310_{G2}, or 310_{G3} may be blue, but the invention is not limited thereto.

Next, step (k) is performed: the transfer stamp approaches the adhesive layer such that the plurality of third light-emitting devices of one third light-emitting device group are in contact with the plurality of corresponding third adhesive bumps, wherein when the plurality of third light-emitting devices of the one third light-emitting device group are in contact with the plurality of third adhesive bumps of one third adhesive bump group, if remaining third light-emitting device groups are on the transfer stamp, then the remaining third light-emitting device groups are staggered with the third adhesive bump groups and are not in contact with the adhesive layer. Specifically, as shown in FIG. 1P, the transfer stamp 200 approaches the adhesive layer 120 such that the plurality of third light-emitting devices 310_{B1} of the third light-emitting device group 300_{B1} are in contact with the plurality of third adhesive bumps 122_{B1} of the corresponding third adhesive bump group 120_{B1}. When the third light-emitting devices 310_{B1} of the third light-emitting device group 300_{B1} are in contact with the third adhesive bumps 122_{B1} of the third adhesive bump group 120_{B1}, if remaining third light-emitting device groups 300_{B2} and 300_{B3} are on the transfer stamp 200, then the plurality of third light-emitting devices 310_{B2} and 310_{B3} of the remaining third light-emitting device groups 300_{B2} and 300_{B3} are staggered with the plurality of third adhesive bumps 122_{B1}, 122_{B2}, and 122_{B3} of the third adhesive bump groups 120_{B1}, 120_{B2}, and 120_{B3} and are not in contact with the adhesive layer 120.

Specifically, when the third light-emitting devices 310_{B1} are in contact with the third adhesive bumps 122_{B1}, the third light-emitting devices 310_{B2} of the third light-emitting device group 300_{B2} are in contact with the first light-emitting devices 310_{R1} on the first adhesive bumps 122_{R1}, and the first light-emitting devices 310_{R1} prevent a contact between the third light-emitting devices 310_{B2} and the adhesive layer 120. Moreover, when the third light-emitting devices 310_{B1} are in contact with the third adhesive bumps 122_{B1}, the third light-emitting devices 310_{B3} of the third light-emitting device group 300_{B3} are in contact with the plurality of second light-emitting devices 310_{G1} and 310_{G2} on the plurality of second adhesive bumps 122_{G1} and 122_{G2}, and the second light-emitting devices 310_{G1} and 310_{G2} prevent a contact between the third light-emitting devices 3101_{B3} and the adhesive layer 120.

Next, step (l) is performed: the transfer stamp is kept away from the adhesive layer such that the plurality of third light-emitting devices of one third light-emitting device group respectively stay on the plurality of third adhesive bumps of one corresponding third adhesive bump group. Specifically, as shown in FIG. 1Q, the transfer stamp 200 is kept away from the adhesive layer 120 such that the plurality of third light-emitting devices 310_{B1} of the third light-emitting device group 300_{B1} respectively stay on the plurality of third adhesive bumps 122_{B1} of the corresponding third adhesive bump group 120_{B1}. Meanwhile, the plurality of third light-emitting devices 310_{B2} and 310_{B3} of the third light-emitting device groups 310_{B2} and 310_{B3} not in contact with the adhesive layer 120 are kept away from the adhesive layer 120 together with the transfer stamp 200 and does not stay on the adhesive layer 120.

Then, step (m) is performed: steps (k) to (l) are repeated at least once such that the plurality of third light-emitting devices of the remaining third light-emitting device groups stay on the plurality of second adhesive bumps of the corresponding third adhesive bump group. Specific description is as follows.

Specifically, as shown in FIG. 1R, the transfer stamp 200 approaches the adhesive layer 120 such that the plurality of third light-emitting devices 310_{B2} of the third light-emitting device group 300_{B2} are in contact with the plurality of third adhesive bumps 122_{B2} of the corresponding third adhesive bump group 120_{B2}. When the third light-emitting devices 310_{B2} of the third light-emitting device group 300_{B2} are in contact with the third adhesive bumps 122_{B2} of the third adhesive bump group 120_{B2}, if remaining third light-emitting device groups 300_{B3} are on the transfer stamp 200, then the plurality of third light-emitting devices 310_{B3} of the remaining third light-emitting device groups 300_{B3} are staggered with the plurality of third adhesive bumps 122_{B1}, 122_{B2}, and 122_{B3} of the third adhesive bump groups 120_{B1}, 120_{B2}, and 120_{B3} and are not in contact with the adhesive layer 120. Specifically, when the third light-emitting devices 310_{B2} are in contact with the third adhesive bumps 122_{B2}, the third light-emitting devices 310_{B2} of the third light-emitting device group 300_{B3} are in contact with the plurality of first light-emitting devices 310_{R2} and 310_{R3} on the first adhesive bumps 122_{R2} and 122_{R3}, and the first light-emitting devices 310_{R2} and 310_{R3} prevent a contact between the third light-emitting devices 310_{B3} of the third light-emitting device group 300_{B3} and the adhesive layer 120.

Referring to FIG. 1S, next, the transfer stamp 200 is kept away from the adhesive layer 120 such that the plurality of third light-emitting devices 3101_{B2} of the third light-emitting device group 300_{B2} respectively stay on the plurality of third adhesive bumps 122_{B2} of the corresponding third adhesive bump group 120_{B2}. Meanwhile, the plurality of third light-emitting devices 310_{B3} of the third light-emitting device group 300_{B3} not in contact with the adhesive layer 120 are kept away from the adhesive layer 120 together with the transfer stamp 200 and does not stay on the adhesive layer 120.

Referring to FIG. 1T, next, the transfer stamp 200 approaches the adhesive layer 120 such that the plurality of third light-emitting devices 310_{B3} of the third light-emitting device group 300_{B3} are in contact with the plurality of third adhesive bumps 122_{B3} of the corresponding third adhesive bump group 120_{B3}. Referring to FIG. 1U, next, the transfer stamp 200 is kept away from the adhesive layer 120 such that the plurality of third light-emitting devices 310_{B3} of the third light-emitting device group 300_{B3} respectively stay on the plurality of third adhesive bumps 122_{B3} of the corresponding third adhesive bump group 120_{B3}. Meanwhile, all of the third light-emitting devices 310_{B1}, 310_{B2}, and 310_{B3} are respectively transferred onto the corresponding third adhesive bumps 122_{B1}, 122_{B2}, and 122_{B3} by the transfer stamp 200 to complete a light-emitting apparatus 100.

Referring to FIG. 1U, the light-emitting apparatus 100 includes a substrate 110, an adhesive layer 120, a plurality of first light-emitting devices 310_{R1}, 310_{R2}, and 310_{R3}, a plurality of second light-emitting devices 310_{G1}, 310_{G2}, and 310_{G3}, and a plurality of third light-emitting devices 310_{B1}, 310_{B2}, and 310_{B3}. The adhesive layer 120 covers the substrate 110 and has a plurality of first adhesive bumps 122_{R1}, 122_{R2}, and 122_{R3}, a plurality of second adhesive bumps 122_{G1}, 122_{G2}, and 122_{G3}, and a plurality of third adhesive bumps 122_{B1}, 122_{B2}, and 122_{B3}. The height H1 of the first adhesive bumps 122_{R1}, 122_{R2}, and 122_{R3} may be greater than the height H2 of the second adhesive bumps 122_{G1}, 122_{G2}, and 122_{G3}, and the height H2 of the second adhesive bumps 122_{G1}, 122_{G2}, and 122_{G3} may be greater than the height H3 of the third adhesive bumps 122_{B1}, 122_{B2}, and 122_{B3}.

The plurality of first light-emitting devices 310_{R1}, 310_{R2}, and 310_{R3} are respectively disposed on the plurality of first adhesive bumps 122_{R1}, 122_{R2}, and 122_{R3} of the adhesive layer 120. The plurality of second light-emitting devices 310_{G1}, 310_{G2}, and 310_{G3} are disposed on the substrate 110 and are staggered with the first adhesive bumps 122_{R1}, 122_{R2}, and 122_{R3}. The plurality of second light-emitting devices 310_{G1}, 310_{G2}, and 310_{G3} are respectively disposed on the plurality of second adhesive bumps 122_{G1}, 122_{G2}, and 122_{G3} of the adhesive layer 120. The plurality of third light-emitting devices 310_{B1}, 310_{B2}, and 310_{B3} are respectively disposed on the plurality of third adhesive bumps 122_{B1}, 122_{B2}, and 122_{B3} of the adhesive layer 120. In particular, a minimum distance D1 of each of the first light-emitting devices 310_{R1}, 310_{R2}, and 310_{R3} and the substrate 110 is greater than a minimum distance D2 of each of the second light-emitting devices 310_{G1}, 310_{G2}, and 310_{G3} and the substrate 110. The minimum distance D2 of each of the second light-emitting devices 310_{G1}, 310_{G2}, and 310_{G3} and the substrate 110 is greater than a minimum distance D3 of each of the third light-emitting devices 310_{B1}, 310_{B2}, and 310_{B3} and the substrate 110. In the embodiment of FIG. 1U, a thickness T1 of the first light-emitting devices 310_{R1}, 310_{R2}, and 310_{R3}, a thickness T2 of the second light-emitting devices 310_{G1}, 310_{G2}, and 310_{G3}, and a thickness T3 of the third light-emitting devices 310_{B1}, 310_{B2}, and 310_{B3} may substantially be the same. However, the invention is not limited thereto, and in other embodiments, the thickness T1 of the first light-emitting devices 310_{R1}, 310_{R2}, and 310_{R3}, the thickness T2 of the second light-emitting devices 310_{G1}, 310_{G2}, and 310_{G3}, and the thickness T3 of the third light-emitting devices 310_{B1}, 310_{B2}, and 310_{B3} may also be different. In the following, description is provided with reference to other figures.

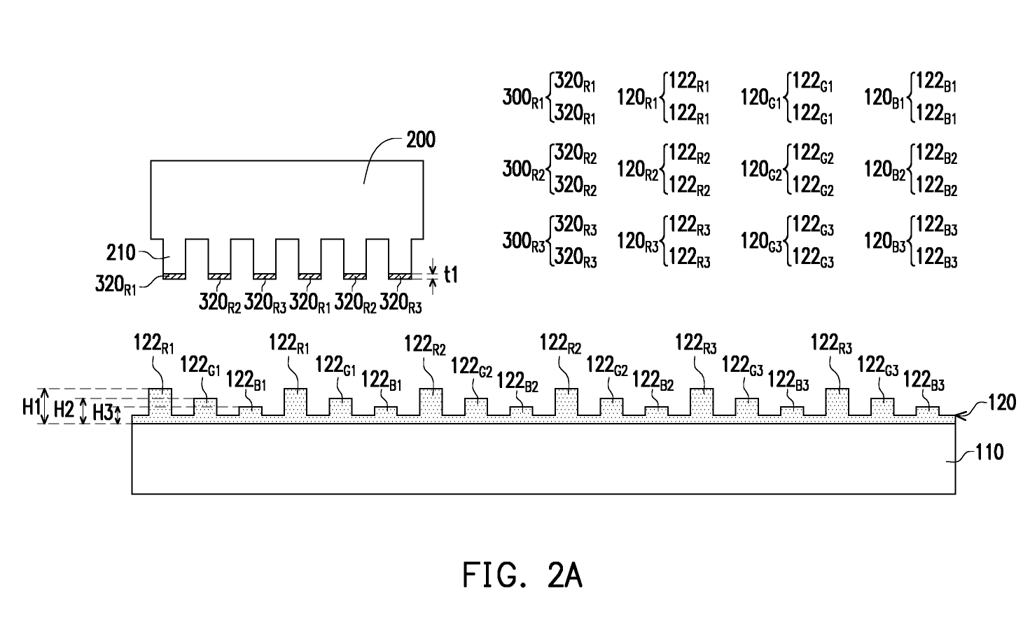

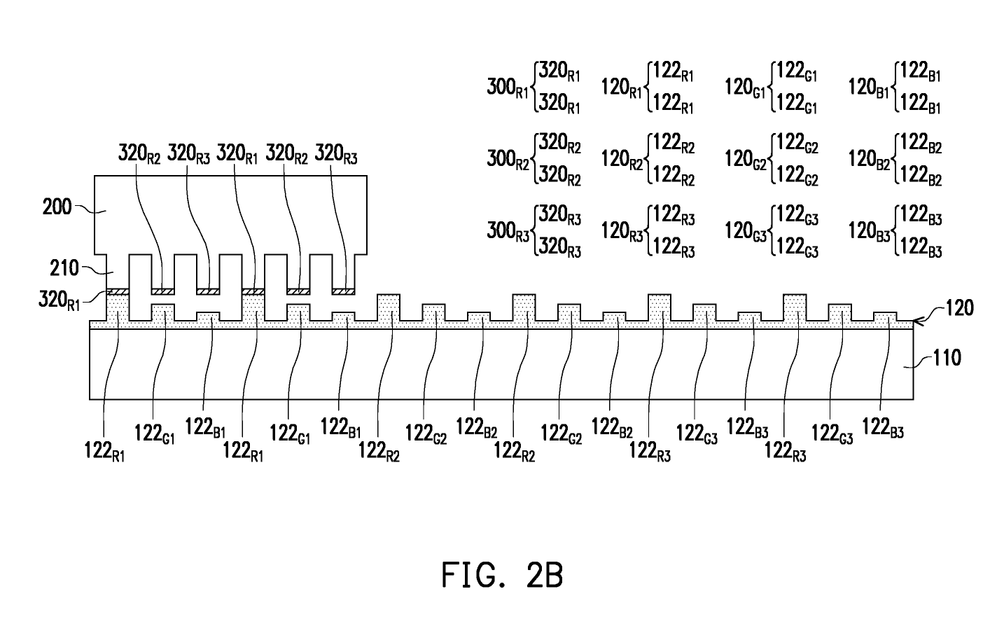

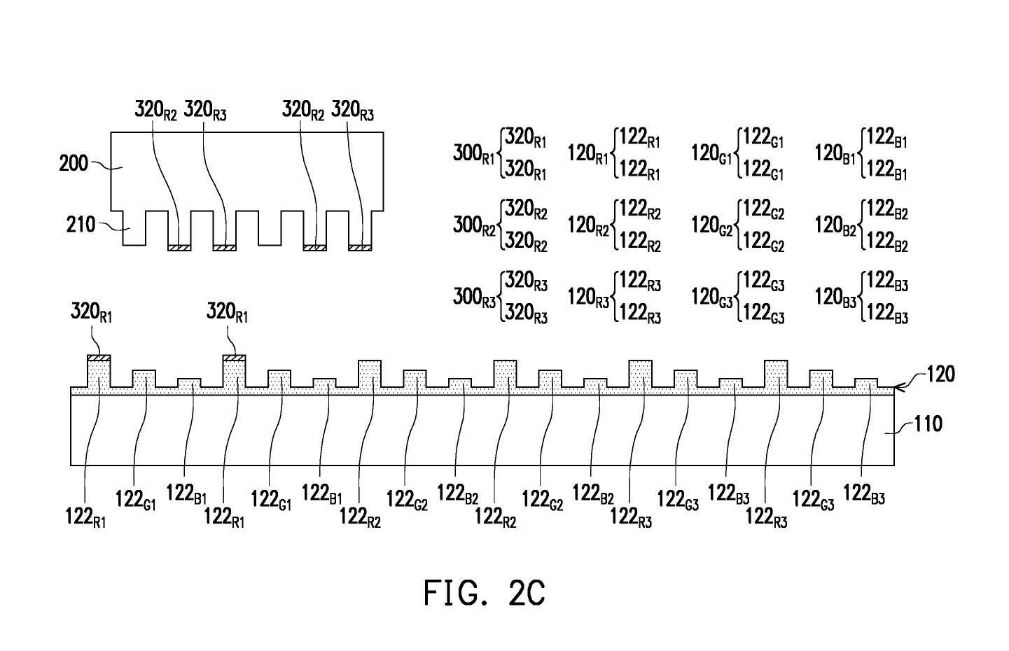

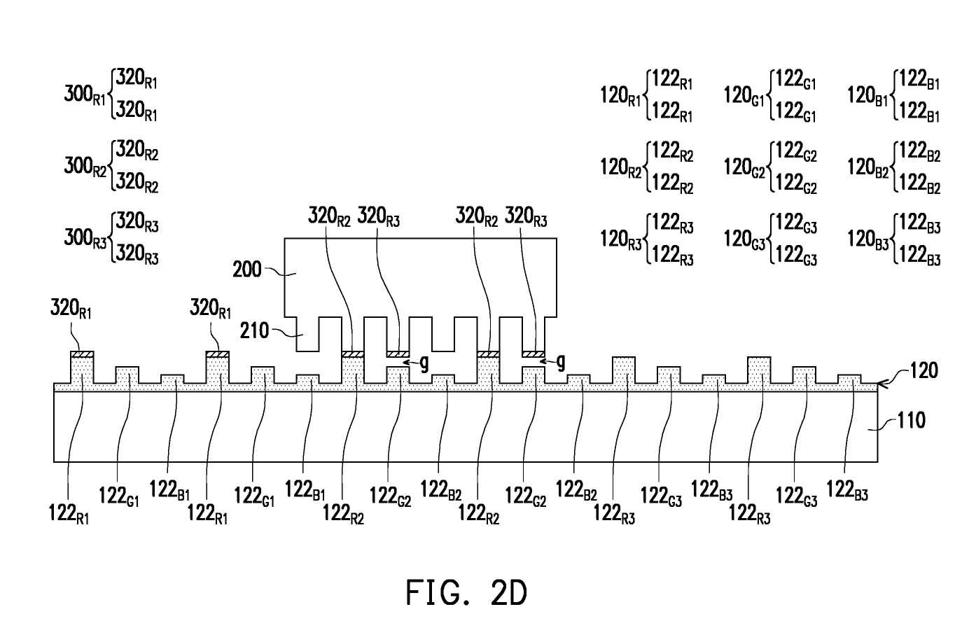

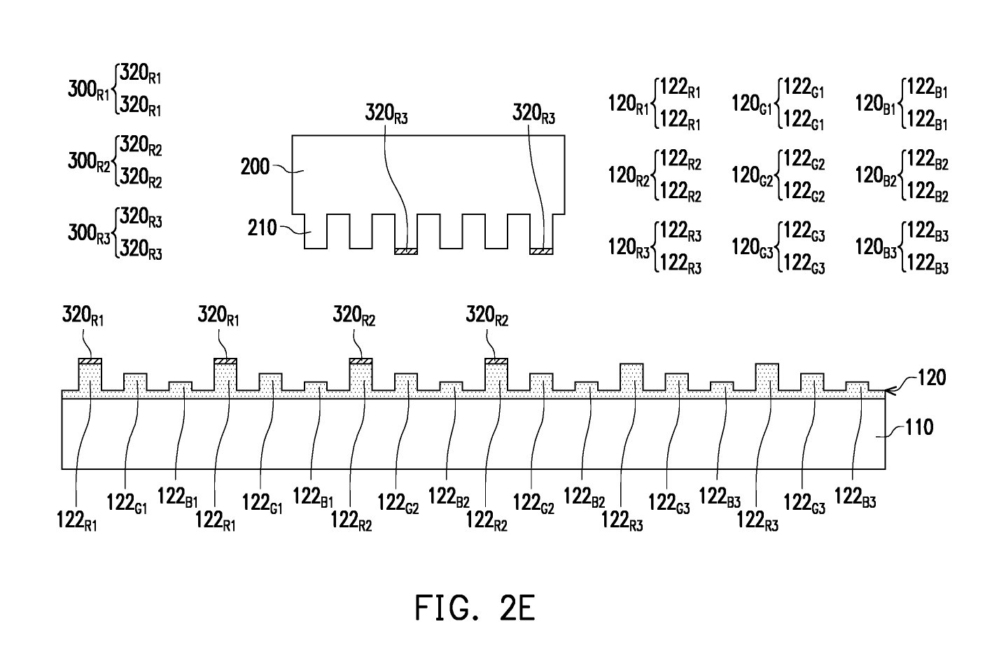

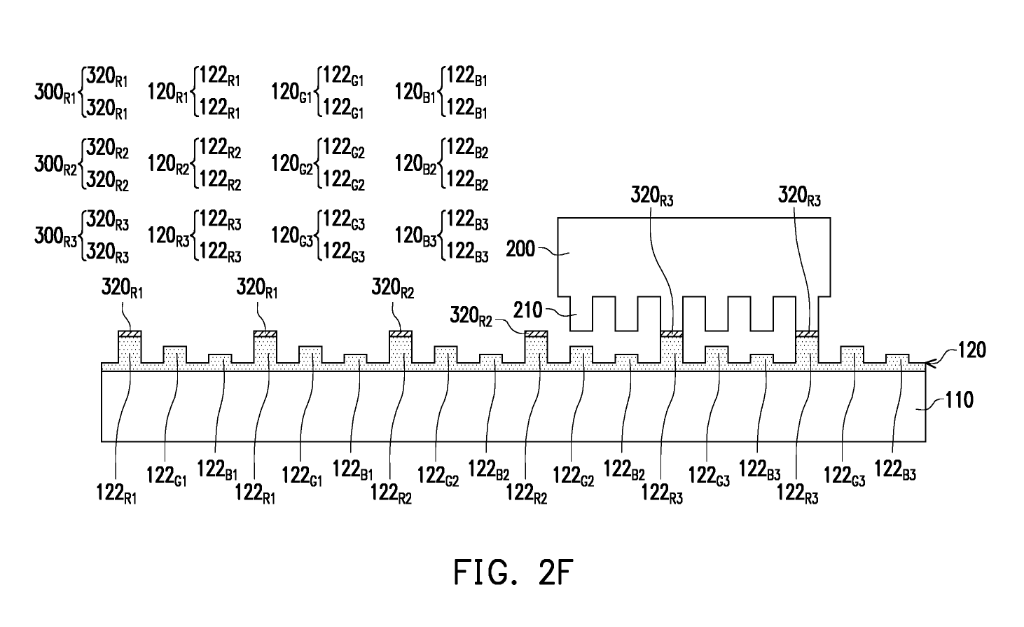

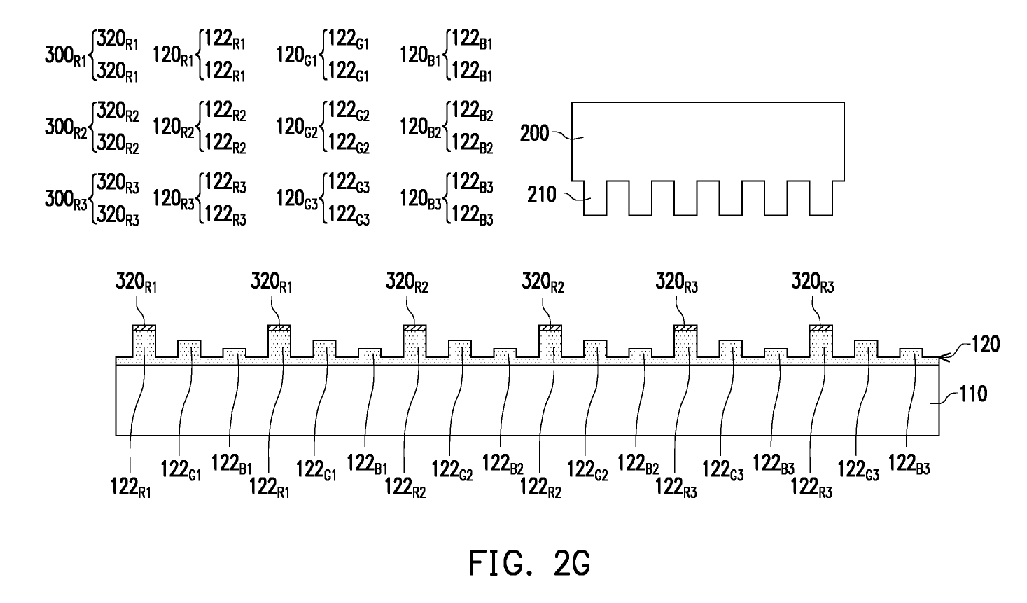

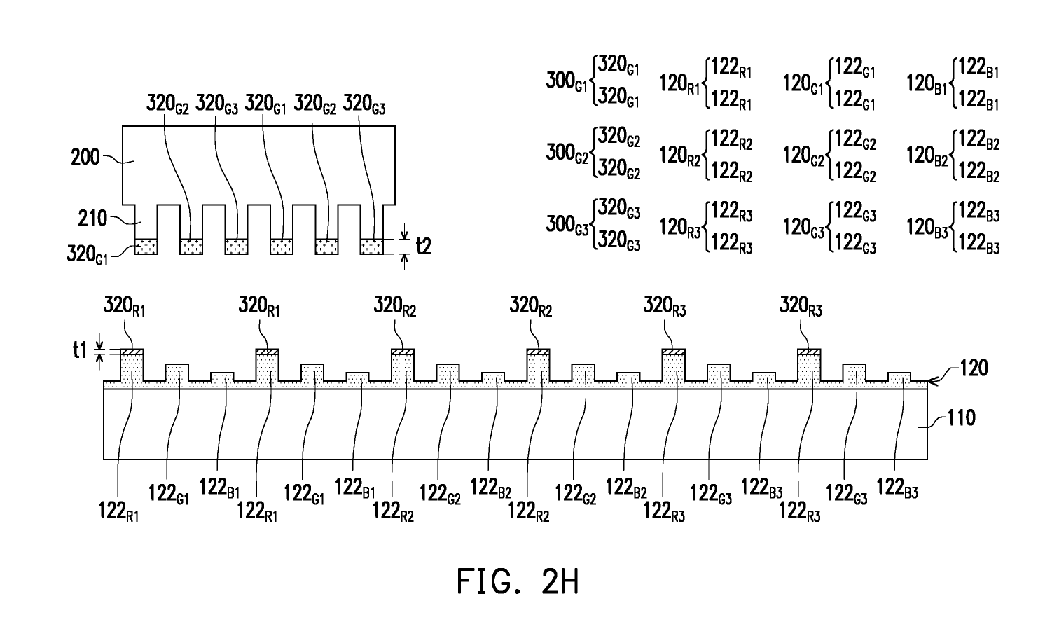

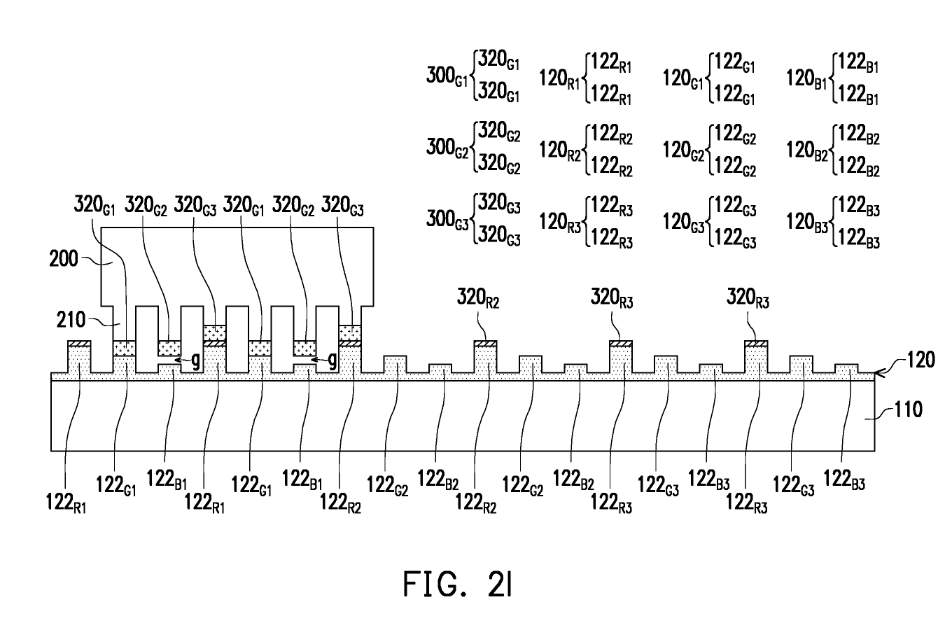

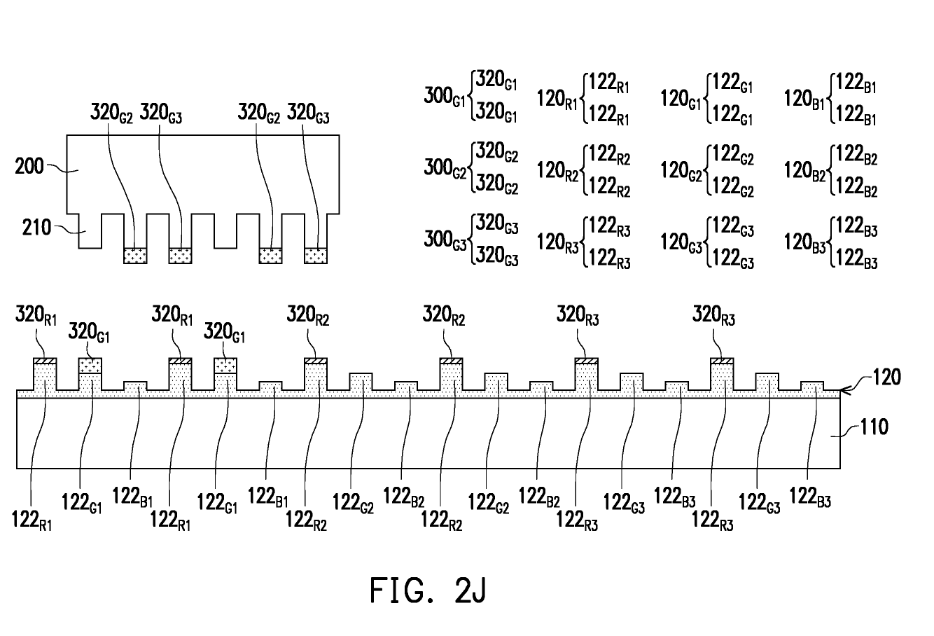

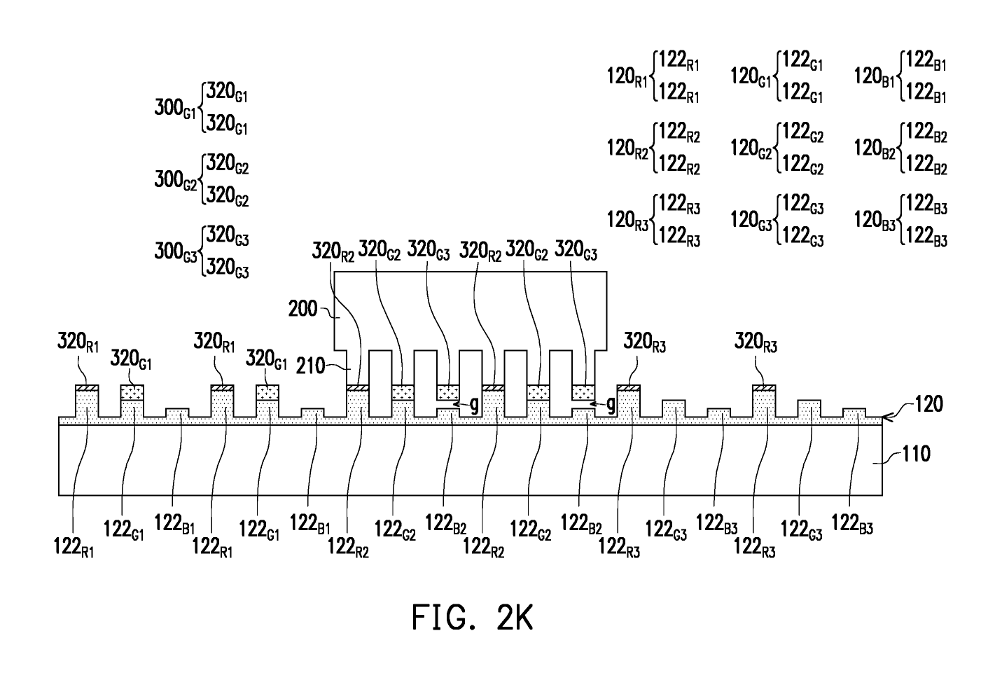

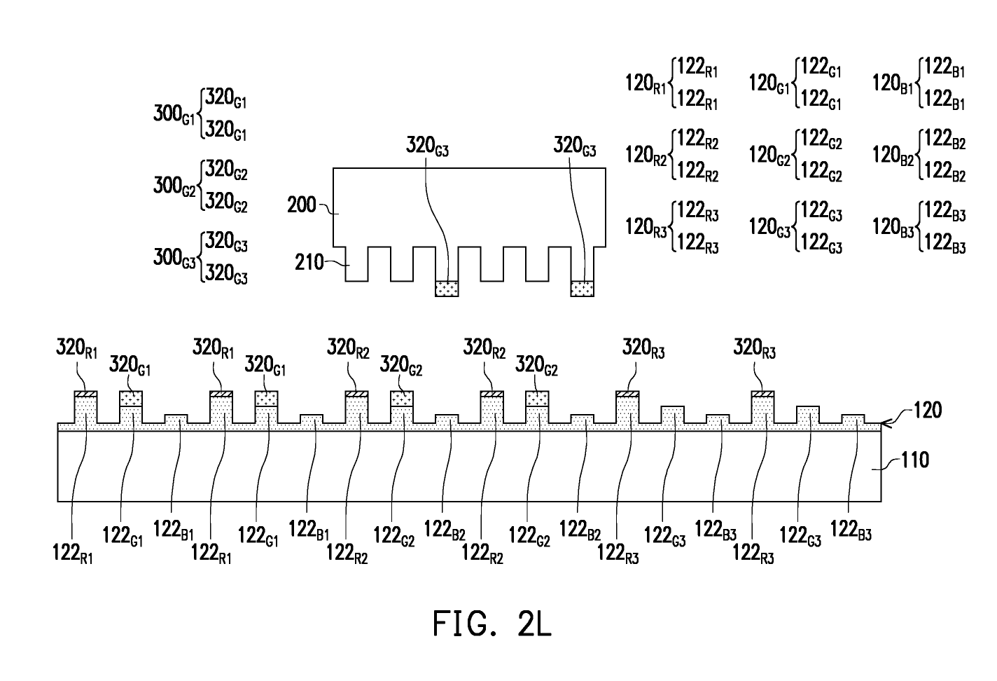

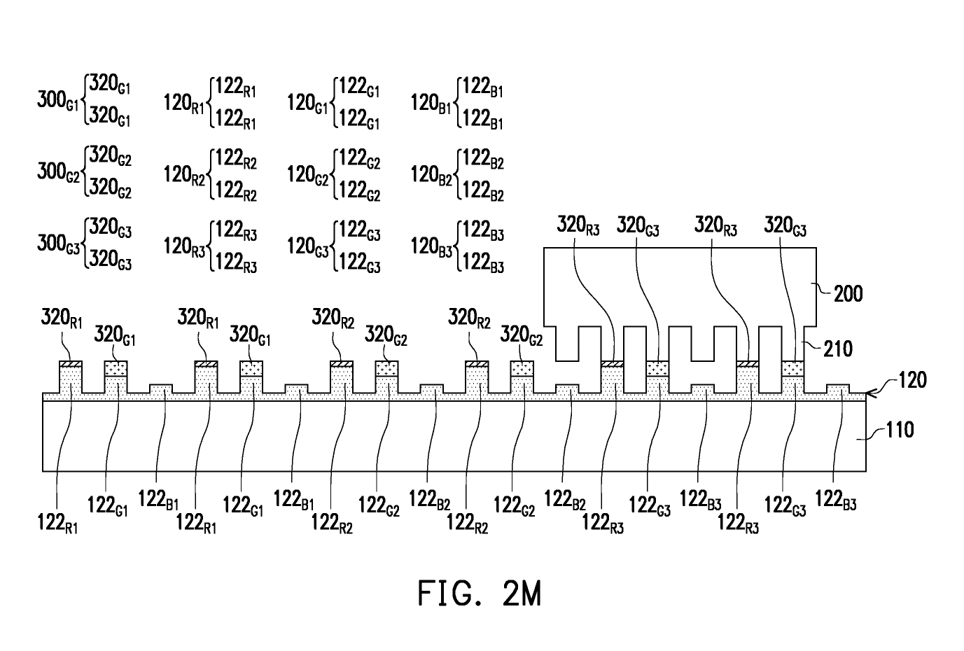

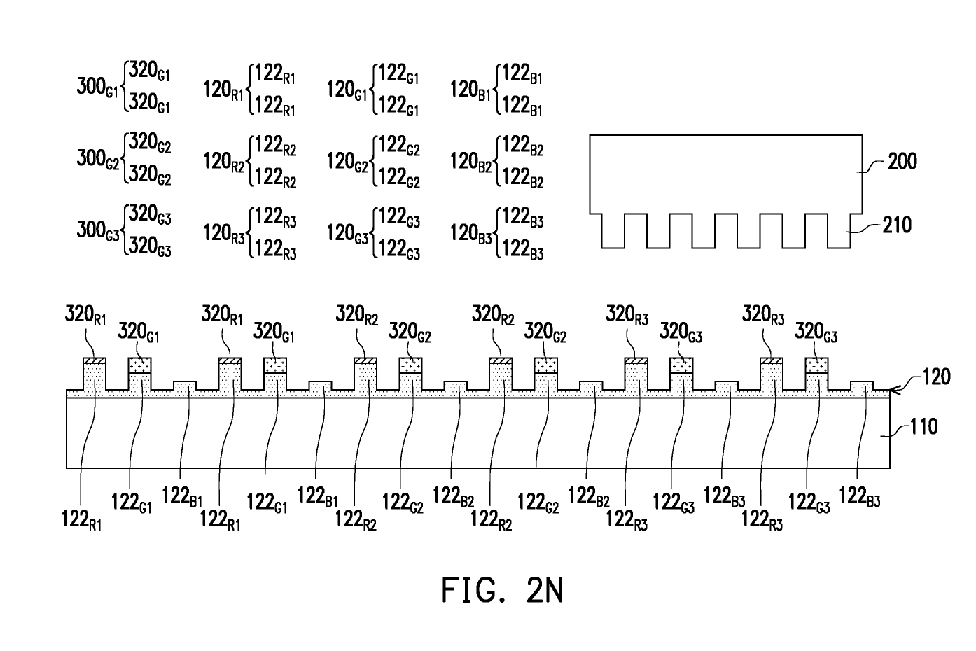

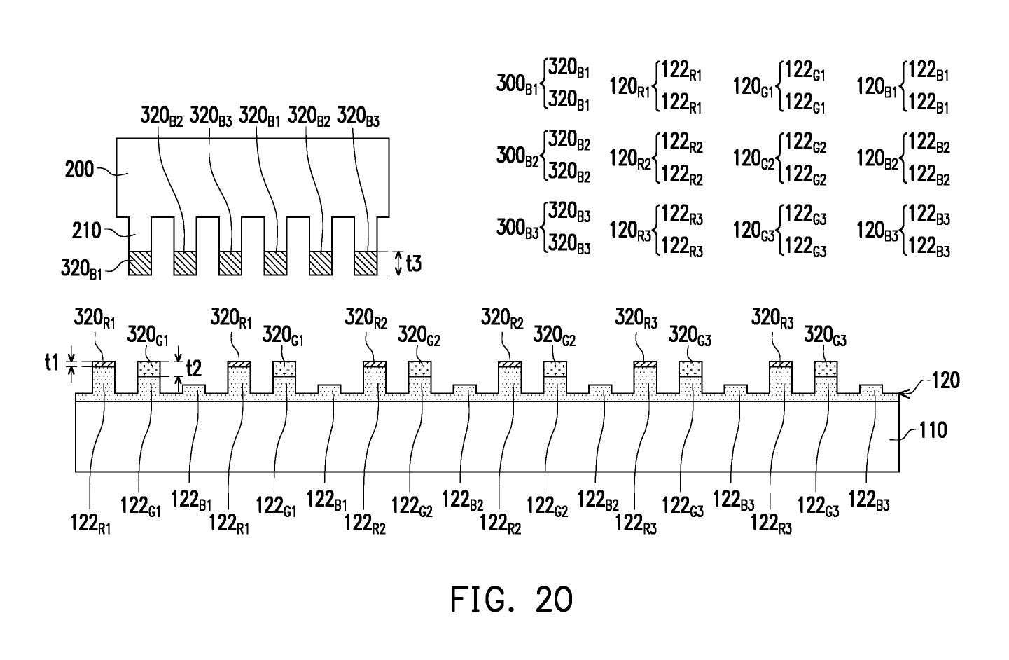

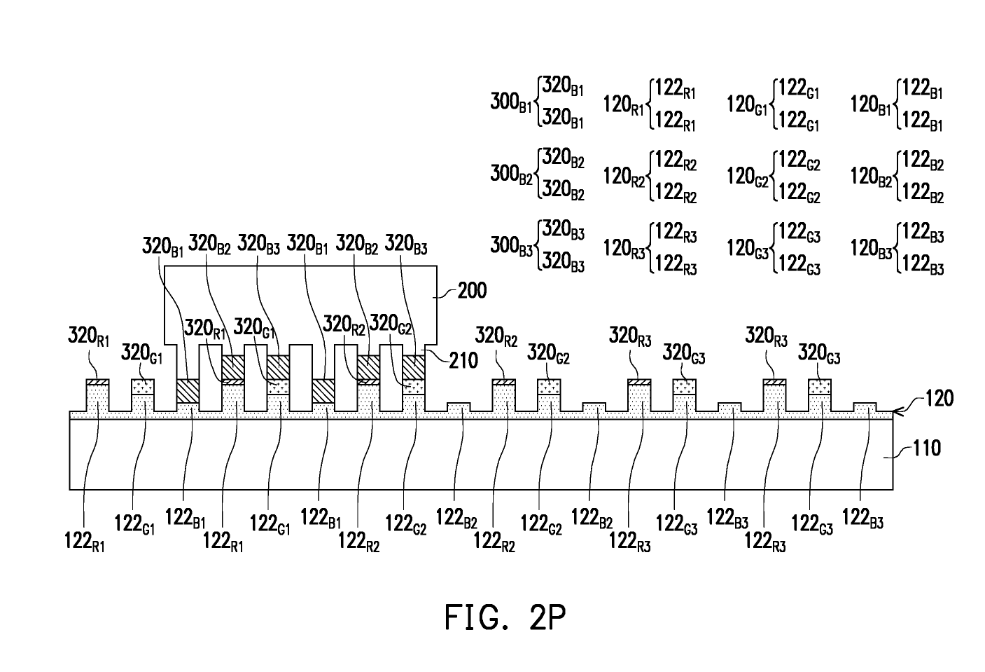

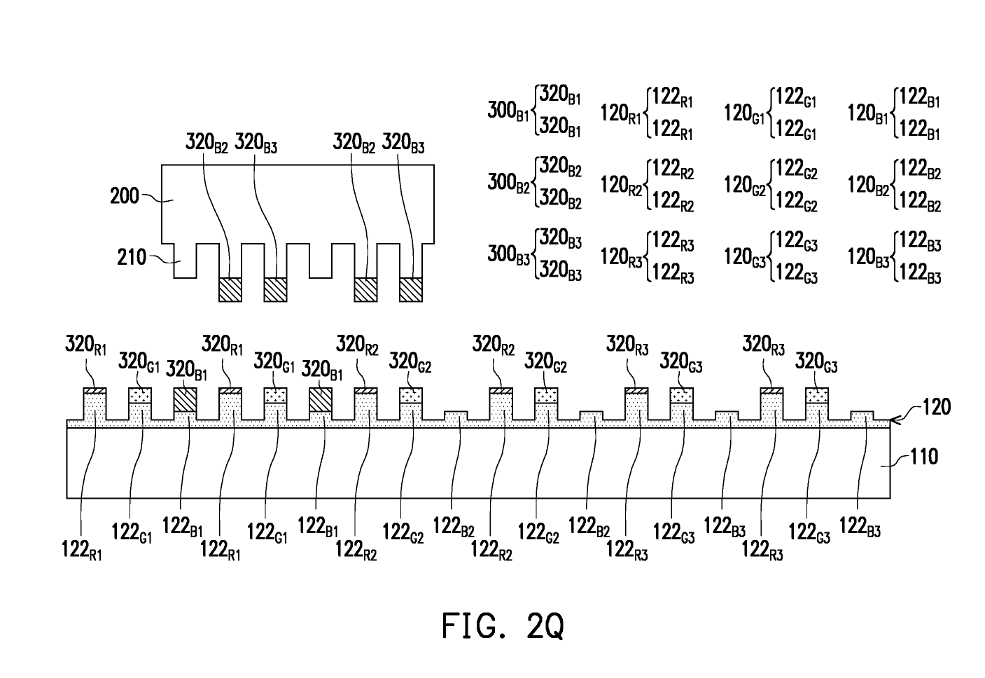

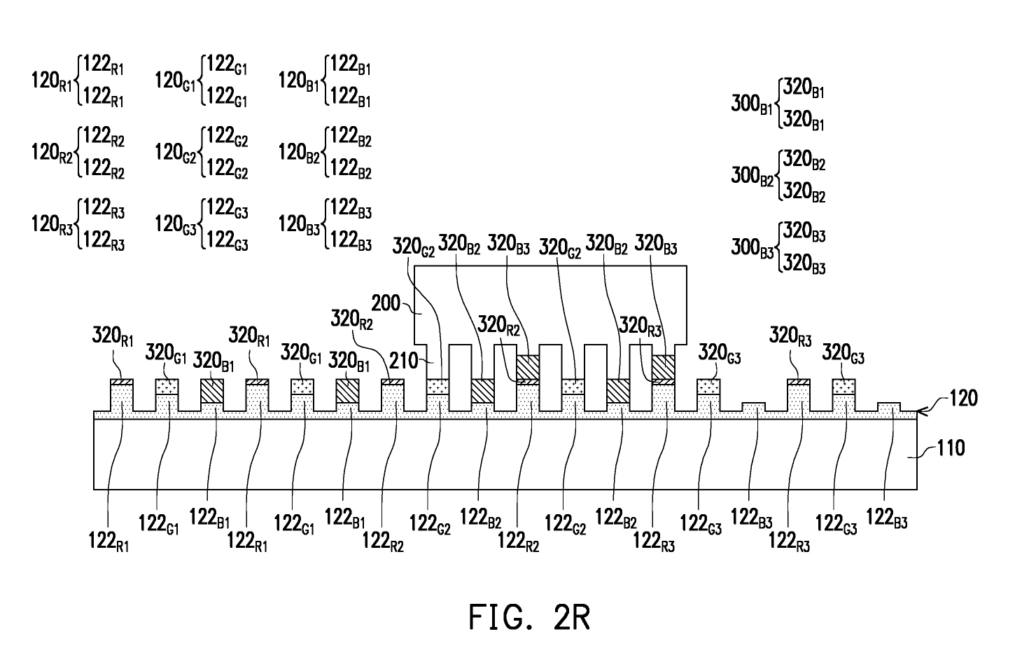

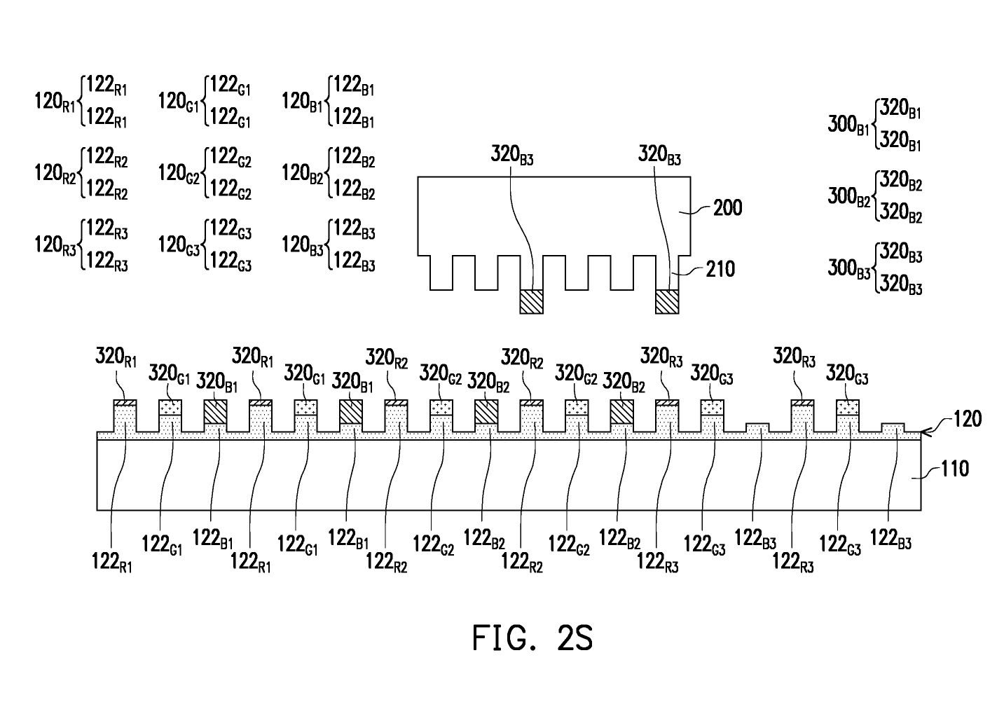

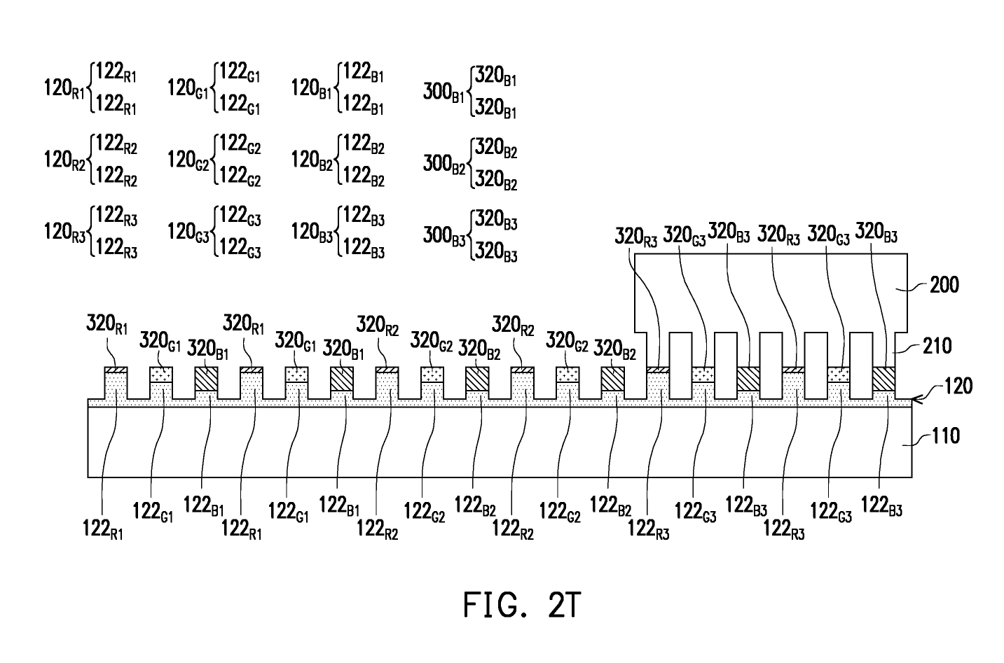

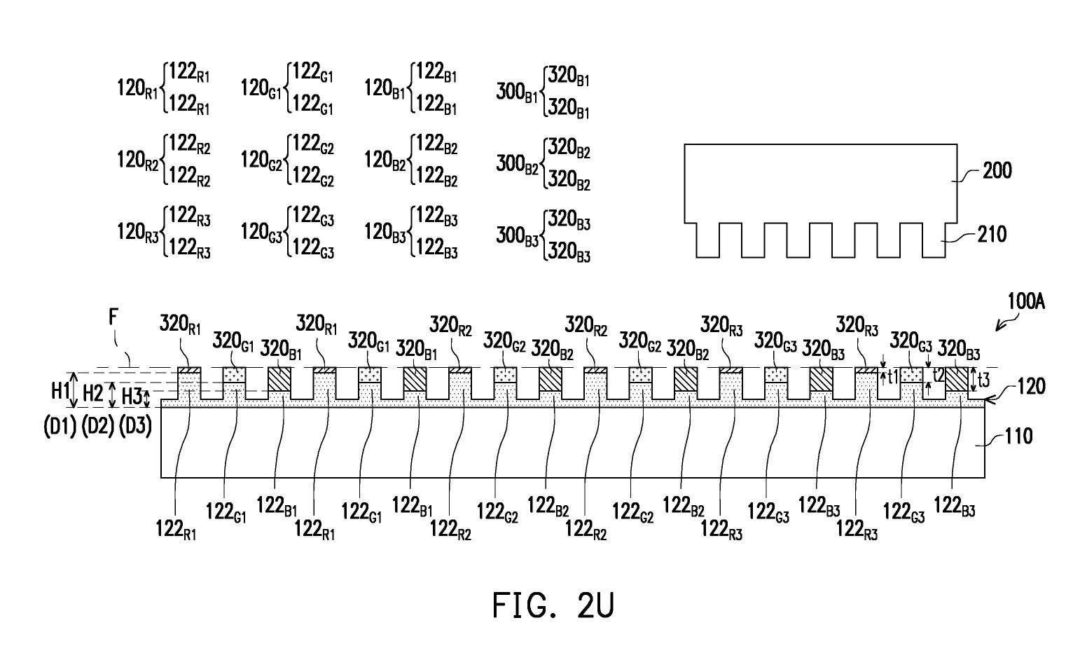

FIG. 2A to FIG. 2U are cross-sectional schematics of a fabricating method of a light-emitting apparatus of another embodiment of the invention. The fabricating method of a light-emitting apparatus of FIG. 2A to FIG. 2U is similar to the fabricating method of a light-emitting apparatus of FIG. 1A to FIG. 1U, and therefore the same or corresponding devices are represented by the same or corresponding reference numerals.

The main difference between the two is: the first light-emitting devices 320_{R1}, 320_{R2}, and 320_{R3}, the second light-emitting devices 320_{G1}, 320_{G2}, and 320_{G3}, and the third light-emitting devices 320_{B1}, 320_{B3}, and 320_{B3} of FIG. 2A to FIG. 2U are not completely the same as the first light-emitting devices 310_{R1}, 310_{R2}, and 310_{R3}, the second light-emitting devices 310_{G1}, 310_{G2}, and 310_{G3}, and the third light-emitting devices 310_{B1}, 310_{B2}, and 310_{B3} of FIG. 1A to FIG. 1U. The following mainly describes this difference, and the same portions between the two are as described above.

Referring first to FIG. 2A, first, step (a) is performed: a substrate 110 and an adhesive layer 120 covering the substrate 110 are provided. Next, step (b) is performed: a transfer stamp 200 picks up a plurality of first light-emitting device groups 300_{R1}, 300_{R2}, and 300_{R3}. Each of the first light-emitting device groups 300_{R1} (300_{R2} or 300_{R3}) includes a plurality of first light-emitting devices 320_{R1} (320_{R2} or 320_{R3}). Each of the first light-emitting devices 320_{R1}, 320_{R2}, and 320_{R3} has a thickness t1.

Referring to FIG. 2B, next, step (c) is performed: the transfer stamp approaches the adhesive layer such that the plurality of first light-emitting devices of one first light-emitting device group are in contact with the plurality of first adhesive bumps of one corresponding first adhesive bump group, wherein when the first light-emitting devices of the first light-emitting device group are in contact with the first adhesive bumps of the first adhesive bump group, if remaining first light-emitting device groups are on the transfer stamp, then the plurality of first light-emitting devices of the remaining first light-emitting device groups are staggered with the plurality of first adhesive bumps of the first adhesive bump group and are not in contact with the adhesive layer. Specifically, the transfer stamp 200 approaches the adhesive layer 120 such that the plurality of first light-emitting devices 320_{R1} of one first light-emitting device group 300_{R1} are in contact with the plurality of first adhesive bumps 122_{R1} of one corresponding first adhesive bump group 120_{R1}. When the first light-emitting devices 320_{R1} of the first light-emitting device group 300_{R1} are in contact with the first adhesive bumps 122_{R1} of the first adhesive bump group 120_{R1}, if remaining first light-emitting device groups 300_{R2} and 300_{R3} are on the transfer stamp 200, then the plurality of first light-emitting devices 310_{R2} and 310_{R3} of the remaining first light-emitting device groups 300_{R2} and 300_{R3} are staggered with the plurality of first adhesive bumps 122_{R1}, 122_{R2}, and 122_{R3} of the first adhesive bump groups 120_{R1}, 120_{R2}, and 120_{R3} and are not in contact with the adhesive layer 120.

Referring to FIG. 2C, next, step (d) is performed: the transfer stamp is kept away from the adhesive layer such that the plurality of first light-emitting devices of one first light-emitting device group respectively stay on the plurality of first adhesive bumps of the corresponding first adhesive bump group. Specifically, the transfer stamp 200 is kept away from the adhesive layer 120 such that the plurality of first light-emitting devices 320_{R1} of the first light-emitting device group 300_{R1} respectively stay on the plurality of first adhesive bumps 122_{R1} of the corresponding first adhesive bump group 120_{R1}. Meanwhile, the plurality of first light-emitting devices 320_{R2} and 320_{R3} of the first light-emitting device groups 310_{R2} and 310_{R3} not in contact with the adhesive layer 120 before is kept away from the adhesive layer 120 together with the transfer stamp 200 and do not stay on the adhesive layer 120.

Then, step (e) is performed: steps (c) to (d) are repeated at least once such that the plurality of first light-emitting devices of the remaining first light-emitting device groups stay on the plurality of first adhesive bumps of the corresponding first adhesive bump group. Specifically, referring to FIG. 2D, after the first light-emitting devices 320_{R1} stay on the first adhesive bumps 122_{R1}, the transfer stamp 200 approaches the adhesive layer 120 such that the plurality of first light-emitting devices 320_{R2} of the first light-emitting device group 300_{R2} are in contact with the plurality of first adhesive bumps 122_{R2} of the corresponding first adhesive bump group 120_{R2}. When the first light-emitting devices 320_{R2} of the first light-emitting device group 300_{R2} are in contact with the first adhesive bumps 122_{R2} of the first adhesive bump group 120_{R2}, if remaining first light-emitting device groups 300_{R3} are on the transfer stamp 200, then the plurality of first light-emitting devices 320_{R3} of the remaining first light-emitting device groups 300_{R3} are staggered with the plurality of first adhesive bumps 122_{R1}, 122_{R2}, and 122_{R3} of the first adhesive bump groups 120ᵣ₁, 120_{R2}, and 120_{R3} and are not in contact with the adhesive layer 120. Referring to FIG. 2E, next, the transfer stamp 200 is kept away from the adhesive layer 120 such that the plurality of first light-emitting devices 320_{R2} of the first light-emitting device group 300_{R2} respectively stay on the plurality of first adhesive bumps 122_{R2} of the corresponding first adhesive bump group 120_{R2}. Meanwhile, the plurality of first light-emitting devices 320_{R3} of the first light-emitting device group 300_{R3} not in contact with the adhesive layer 120 before are kept away from the adhesive layer 120 together with the transfer stamp 200 and do not stay on the adhesive layer 120.

Referring to FIG. 2F, after the first light-emitting devices 320_{R1} and 320_{R2} respectively stay on the corresponding first adhesive bumps 122_{R1} and 122_{R2}, the transfer stamp 200 approaches the adhesive layer 120 such that the plurality of first light-emitting devices 320_{R3} of the first light-emitting device groups 300_{R3} are in contact with the plurality of first adhesive bumps 122_{R3} of the corresponding first adhesive bump group 120_{R3}. As shown in FIG. 2G, next, the transfer stamp 200 is kept away from the adhesive layer 120 such that the plurality of first light-emitting devices 320_{R3} of the first light-emitting device group 300_{R3} respectively stay on the plurality of first adhesive bumps 122_{R3} of the corresponding first adhesive bump group 120_{R3}. Meanwhile, all of the first light-emitting devices 320_{R1}, 320_{R2}, and 320_{R3} are respectively transferred onto the corresponding first adhesive bumps 122_{R1}, 122_{R2}, and 122_{R3} by the transfer stamp 200.

Referring to FIG. 2H, next, step (f) is performed: the transfer stamp 200 picks up a plurality of second light-emitting device groups 300_{G1}, 300_{G2}, and 300_{G3}. Each of the second light-emitting device groups 300_{G1} (300_{G2} or 300_{G3}) includes a plurality of second light-emitting devices 320_{G1} (320_{G2} or 320_{G3}). Each of the second light-emitting devices 320_{G1}, 320_{G2}, and 320_{G3} has a thickness t2. The thickness t2 of the second light-emitting devices 320_{G1}, 320_{G2}, and 320_{G3} is greater than the thickness t1 of the first light-emitting devices 320_{R1}, 320_{R2}, and 320_{R3}.

Referring to FIG. 21, next, step (g) is performed: the transfer stamp approaches the adhesive layer such that the plurality of second light-emitting devices of one second light-emitting device group are in contact with the plurality of second adhesive bumps of one corresponding second adhesive bump group, wherein when the second light-emitting devices of the second light-emitting device group are in contact with the second adhesive bumps of the second adhesive bump group, if remaining second light-emitting device groups stay on the transfer stamp, then the plurality of second light-emitting devices of the remaining second light-emitting device groups are staggered with the plurality of second adhesive bumps of the second adhesive bump group and are not in contact with the adhesive layer. Specifically, as shown in FIG. 21, the transfer stamp 200 approaches the adhesive layer 120 such that the plurality of second light-emitting devices 320_{G1} of one second light-emitting device group 300_{G1} are in contact with the plurality of second adhesive bumps 122_{G1} of the corresponding second adhesive bump group 120_{G1}. When the second light-emitting devices 320_{G1} of the second light-emitting device group 300_{G1} are in contact with the second adhesive bumps 122_{G1} of the second adhesive bump group 120_{G1}, if remaining second light-emitting device groups 300_{G2} and 300_{G3} are on the transfer stamp 200, then the plurality of second light-emitting devices 320_{G2} and 320_{G3} of the remaining second light-emitting device groups 300_{G2} and 300_{G3} are staggered with the plurality of second adhesive bumps 122_{G1}, 122_{G2}, and 122_{G3} of the second adhesive bump groups 120_{G1}, 120_{G2}, and 120_{G3} and are not in contact with the adhesive layer 120.

Next, step (h) is performed: the transfer stamp is kept away from the adhesive layer such that the plurality of second light-emitting devices of one second light-emitting device group respectively stay on the plurality of second adhesive bumps of the corresponding second adhesive bump group. Specifically, as shown in FIG. 2J, the transfer stamp 200 is formed away from the adhesive layer 120 such that the plurality of second light-emitting devices 320_{G1} of the second light-emitting device group 300_{G1} respectively stay on the plurality of second adhesive bumps 122_{G1} of the corresponding second adhesive bump group 120_{G1}. Meanwhile, the plurality of second light-emitting devices 320_{G2} and 320_{G3} of the second light-emitting device groups 300_{G2} and 300_{G3} not in contact with the adhesive layer 120 before are kept away from the adhesive layer 120 together with the transfer stamp 200 and do not stay on the adhesive layer 120.

Then, step (i) is performed: steps (g) to (h) are repeated at least once such that the plurality of second light-emitting devices of the remaining second light-emitting device groups stay on the plurality of second adhesive bumps of the corresponding second adhesive bump group.

Specifically, as shown in FIG. 2K, next, the transfer stamp 200 approaches the adhesive layer 120 such that the plurality of second light-emitting devices 310_{G2} of the second light-emitting device group 300_{G2} are in contact with the plurality of second adhesive bumps 122_{G2} of the corresponding second adhesive bump group 120_{G2}. When the second light-emitting devices 320_{G2} of the second light-emitting device group 300_{G2} are in contact with the second adhesive bumps 122_{G2} of the second adhesive bump group 120_{G2}, if remaining second light-emitting device groups 300_{G3} are on the transfer stamp 200, then the plurality of second light-emitting devices 320_{G3} of the remaining second light-emitting device groups 300_{G3} are staggered with the plurality of second adhesive bumps 122_{G1}, 122_{G2}, and 122_{G3} of the second adhesive bump groups 120_{G1}, 120_{G2}, and 120_{G3} and are not in contact with the adhesive layer 120.

As shown in FIG. 2L, next, the transfer stamp 200 is kept away from the adhesive layer 120 such that the plurality of second light-emitting devices 320_{G2} of the second light-emitting device group 300_{G2} respectively stay on the plurality of second adhesive bumps 122_{G2} of the corresponding second adhesive bump group 120_{G2}. Meanwhile, the plurality of second light-emitting devices 320_{G3} of the second light-emitting device group 300_{G3} not in contact with the adhesive layer 120 before are kept away from the adhesive layer 120 together with the transfer stamp 200 and do not stay on the adhesive layer 120.

As shown in FIG. 2M, next, the transfer stamp 200 approaches the adhesive layer 120 again such that the plurality of second light-emitting devices 320_{G3} of the second light-emitting device group 300_{G3} are in contact with the plurality of second adhesive bumps 122_{G3} of the corresponding second adhesive bump group 120_{G3}. As shown in FIG. 2N, next, the transfer stamp 200 is kept away from the adhesive layer 120 such that the plurality of second light-emitting devices 320_{G3} of the second light-emitting device group 300_{G3} respectively stay on the plurality of second adhesive bumps 122_{G3} of the corresponding second adhesive bump group 120_{G3}. Meanwhile, all of the second light-emitting devices 320_{G1}, 320_{G2}, and 320_{G3} are respectively transferred onto the corresponding second adhesive bumps 122_{G1}, 122_{G2}, and 122_{G3} by the transfer stamp 200.

Referring to FIG. 20, next, step (j) is performed: the transfer stamp 200 picks up a plurality of third light-emitting device groups 300_{B1}, 300_{B2}, and 300_{B3}. Each of the third light-emitting device groups 300_{B1} (300_{B2} or 300_{B3}) includes a plurality of third light-emitting devices 320_{B1} (320_{B2} or 320_{B3}). Each of the third light-emitting devices 320_{B1}, 320_{B2}, and 320_{B3} has a thickness t3. The thickness t3 of the third light-emitting devices 320_{B1}, 320_{B2}, and 320_{B3} is greater than the thickness t2 of the second light-emitting devices 320_{G1}, 320_{G2}, and 320_{G3}.

Next, step (k) is performed: the transfer stamp approaches the adhesive layer such that the plurality of third light-emitting devices of one third light-emitting device group are in contact with the plurality of corresponding third adhesive bumps, wherein when the plurality of third light-emitting devices of the one third light-emitting device group are in contact with the plurality of third adhesive bumps of one third adhesive bump group, if remaining third light-emitting device groups are on the transfer stamp, then the remaining third light-emitting device groups are staggered with the third adhesive bump groups and are not in contact with the adhesive layer. Specifically, as shown in FIG. 2P, the transfer stamp 200 approaches the adhesive layer 120 such that the plurality of third light-emitting devices 320_{B1} of the third light-emitting device group 300_{B1} are in contact with the plurality of third adhesive bumps 122_{B1} of the corresponding third adhesive bump group 120_{B1}. When the third light-emitting devices 320_{B1} of the third light-emitting device group 300_{B1} are in contact with the third adhesive bumps 122_{B1} of the third adhesive bump group 120_{B1}, if remaining third light-emitting device groups 300_{B2} and 300_{B3} are on the transfer stamp 200, then the plurality of third light-emitting devices 320_{B2} and 320_{B3} of the remaining third light-emitting device groups 300_{B2} and 300_{B3} are staggered with the plurality of third adhesive bumps 122_{B1}, 122_{B2}, and 122_{B3} of the third adhesive bump groups 120_{B1}, 120_{B2}, and 120_{B3} and are not in contact with the adhesive layer 120.

Next, step (l) is performed: the transfer stamp is kept away from the adhesive layer such that the plurality of third light-emitting devices of one third light-emitting device group respectively stay on the plurality of third adhesive bumps of one corresponding third adhesive bump group. Specifically, as shown in FIG. 2Q, the transfer stamp 200 is kept away from the adhesive layer 120 such that the plurality of third light-emitting devices 320_{B1} of the third light-emitting device group 300_{B1} respectively stay on the plurality of third adhesive bumps 122_{B1} of the corresponding third adhesive bump group 120_{B1}. Meanwhile, the plurality of third light-emitting devices 320_{B2} and 320_{B3} of the third light-emitting device groups 310_{B2} and 310_{B3} not in contact with the adhesive layer 120 are kept away from the adhesive layer 120 together with the transfer stamp 200 and do not stay on the adhesive layer 120.

Referring to FIG. 2R to FIG. 2U, next, step (m) is performed: steps (k) to (l) are repeated at least once such that the plurality of third light-emitting devices of the remaining third light-emitting device groups stay on the plurality of second adhesive bumps of the corresponding third adhesive bump group.

Specifically, as shown in FIG. 2R, the transfer stamp 200 approaches the adhesive layer 120 such that the plurality of third light-emitting devices 320_{B2} of the third light-emitting device group 300_{B2} are in contact with the plurality of third adhesive bumps 122_{B2} of the corresponding third adhesive bump group 120_{B2}. When the third light-emitting devices 310_{B2} of the third light-emitting device group 300_{B2} are in contact with the third adhesive bumps 122_{B2} of the third adhesive bump group 120_{B2}, if remaining third light-emitting device groups 300_{B3} are on the transfer stamp 200, then the plurality of third light-emitting devices 320_{B3} of the remaining third light-emitting device groups 300_{B3} are staggered with the plurality of thrd adhesive bumps 122_{B1}, 122_{B2}, and 122_{B3} of the third adhesive bump groups 120_{B1}, 120_{B2}, and 120_{B3} are not in contact with the adhesive layer 120.

Referring to FIG. 2S, next, the transfer stamp 200 is kept away from the adhesive layer 120 such that the plurality of third light-emitting devices 320_{B2} of the third light-emitting device group 300_{B2} respectively stay on the plurality of third adhesive bumps 122_{B2} of the corresponding third adhesive bump group 120_{B2}. Meanwhile, the plurality of third light-emitting devices 320_{B3} of the third light-emitting device group 300_{B3} not in contact with the adhesive layer 120 before are kept away from the adhesive layer 120 together with the transfer stamp 200 and do not stay on the adhesive layer 120.

Referring to FIG. 2T, next, the transfer stamp 200 approaches the adhesive layer 120 such that the plurality of third light-emitting devices 320_{B3} of the third light-emitting device group 300_{B3} are in contact with the plurality of third adhesive bumps 122_{B3} of the corresponding third adhesive bump group 120_{B3}. Referring to FIG. 2U, next, the transfer stamp 200 is kept away from the adhesive layer 120 such that the plurality of third light-emitting devices 320_{B3} of the third light-emitting device group 300_{B3} respectively stay on the plurality of third adhesive bumps 122_{B3} of the corresponding third adhesive bump group 120_{B3}. Meanwhile, all of the third light-emitting devices 320_{B1}, 320_{B2}, and 320_{B3} are respectively transferred onto the corresponding third adhesive bumps 122_{B1}, 122_{B2}, and 122_{B3} by the transfer stamp 200 to complete a light-emitting apparatus 100A.

Referring to FIG. 2U, the light-emitting apparatus 100A includes a substrate 110, an adhesive layer 120, a plurality of first light-emitting devices 320_{R1}, 320_{R2}, and 320_{R3}, a plurality of second light-emitting devices 320_{G1}, 320_{G2}, and 320_{G3}, and a plurality of third light-emitting devices 320_{B1}, 320_{B2}, and 320_{B3}. The adhesive layer 120 covers the substrate 110 and has a plurality of first adhesive bumps 122_{R1}, 122_{R2}, and 122_{R3}, a plurality of second adhesive bumps 122_{G1}, 122_{G2}, and 122_{G3}, and a plurality of third adhesive bumps 122_{B1}, 122_{B2}, and 122_{B3}. The height H1 of the first adhesive bumps 122_{R1}, 122₂, and 122_{R3} may be greater than the height H2 of the second adhesive bumps 122_{G1}, 122_{G2}, and 122_{G3}, and the height H2 of the second adhesive bumps 122_{G1}, 122_{G2}, and 122_{G3} may be greater than the height H3 of the third adhesive bumps 122_{B1}, 122_{B2}, and 122_{B3}.

The plurality of first light-emitting devices 320_{R1}, 320_{R2}, and 320_{R3} are respectively disposed on the plurality of first adhesive bumps 122_{R1}, 122_{R2}, and 122_{R3} of the adhesive layer 120. The plurality of second light-emitting devices 320_{G1}, 320_{G2}, and 320_{G3} are disposed on the substrate 110 and are staggered with the plurality of first adhesive bumps 122_{R1}, 122_{R2}, and 122_{R3}. The plurality of second light-emitting devices 320_{G1}, 320_{G2}, and 320_{G3} are respectively disposed on the plurality of second adhesive bumps 122_{G1}, 122_{G2}, and 122_{G3} of the adhesive layer 120. The plurality of third light-emitting devices 320_{B1}, 320_{B2}, and 320_{B3} are respectively disposed on the plurality of third adhesive bumps 122_{B1}, 122_{B2}, and 122_{B3} of the adhesive layer 120. A minimum distance D1 of each of the first light-emitting devices 320_{R1}, 320_{R2}, and 320_{R3} and the substrate 110 is greater than a minimum distance D2 of each of the second light-emitting devices 320_{G1}, 320_{G2}, and 320_{G3} and the substrate 110. The minimum distance D2 of each of the second light-emitting devices 320_{G1}, 320_{G2}, and 320_{G3} and the substrate 110 is greater than a minimum distance D3 of each of the third light-emitting devices 320_{B1}, 320_{B2}, and 320_{B3} and the substrate 110.

Based on the above, in the present embodiment, since the first light-emitting devices 310_{R1}, 310_{R2}, and 310_{R3} have a thickness t1, the second light-emitting devices 310_{G1}, 310_{G2}, and 310_{G3} have a thickness t2, and the third light-emitting devices 310_{B1}, 310_{B2}, and 310_{B3} have a thickness t3, t1<t2<t3. More specifically, in the present embodiment, the sum of the thickness t1 of each of the first light-emitting devices 310_{R1}, 310_{R2}, and 310_{R3} and the height H1 of the corresponding first adhesive bumps 122_{R1}, 122_{R2}, and 122_{R3}, the sum of the thickness t2 of each of the second light-emitting devices 310_{G1}, 310_{G2}, and 310_{G3} and the height H2 of the corresponding second adhesive bumps 122_{G1}, 122_{G2}, and 122_{G3}, and the sum of the thickness t3 of each of the third light-emitting devices 310_{B1}, 310_{B2}, and 310_{B3} and the height H3 of the corresponding third adhesive bumps 122_{B1}, 122_{B2}, and 122_{B3} may substantially be the same; that is, (t1+H1)=(t2+H2)=(t3+H3). The light-emitting surfaces of the first light-emitting devices 310_{R1}, 310_{R2}, and 310_{R3}, the light-emitting surfaces of the second light-emitting devices 310_{G1}, 310_{G2}, and 310_{G3}, and the light-emitting surfaces of the third light-emitting devices 310_{B1}, 310_{B2}, and 310_{B3} may substantially be located on a same horizontal plane F to improve the optical properties of the light-emitting apparatus 100A.

Based on the above, in the fabricating method of a light-emitting apparatus of an embodiment of the invention, the transfer stamp carrying a plurality of first light-emitting devices approaches the adhesive layer such that a portion of the first light-emitting devices (target first light-emitting devices) to be picked up are in contact with a plurality of corresponding first adhesive bumps. Meanwhile, the remaining first light-emitting devices (non-target first light-emitting devices) not to be transferred are staggered with the first adhesive bumps and are not easy to be in contact with the adhesive layer. Accordingly, the probability that the transfer stamp leaves the non-target first light-emitting devices on the adhesive layer is significantly reduced, and therefore the process yield of the light-emitting apparatus is increased.

Similarly, the transfer stamp carrying a plurality of second light-emitting devices approaches the adhesive layer such that a portion of the second light-emitting devices (target second light-emitting devices) to be picked up are in contact with a plurality of second corresponding adhesive bumps. Meanwhile, the remaining second light-emitting devices (non-target second light-emitting devices) not to be transferred are staggered with the second adhesive bumps and are not easy to be in contact with the adhesive layer. More specifically, a portion of the remaining second light-emitting devices (non-target second light-emitting devices) are blocked by the first light-emitting devices already disposed on the adhesive layer and are easy to be in contact with the adhesive layer; a gap is formed between another portion of the remaining second light-emitting devices (non-target second light-emitting devices) and the adhesive layer such that the other portion of the remaining second light-emitting devices (non-target second light-emitting devices) are not easy to be in contact with the adhesive layer. Accordingly, the probability that the transfer stamp leaves the non-target second light-emitting devices on the adhesive layer is significantly reduced, and therefore the process yield of the light-emitting apparatus is increased.

Similarly, the transfer stamp carrying a plurality of third light-emitting devices approaches the adhesive layer such that a portion of the third light-emitting devices (target third light-emitting devices) to be picked up are in contact with a plurality of corresponding third adhesive bumps. Meanwhile, the remaining third light-emitting devices (non-target second light-emitting devices) not to be transferred are staggered with the third adhesive bumps and are not easy to be in contact with the adhesive layer. More specifically, a portion of the remaining third light-emitting devices (non-target second light-emitting devices) are blocked by the first light-emitting devices and/or the second light-emitting devices already disposed on the adhesive layer and are not easy to be in contact with the adhesive layer. Accordingly, the probability that the transfer stamp leaves the non-target third light-emitting devices on the adhesive layer is significantly reduced, and therefore the process yield of the light-emitting apparatus is increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A light-emitting apparatus, comprising:
a substrate;
an adhesive layer covering the substrate and having a plurality of first adhesive bumps;
a plurality of first light-emitting devices respectively disposed on the first adhesive bumps of the adhesive layer; and
a plurality of second light-emitting devices disposed on the substrate and staggered with the first adhesive bumps, wherein a minimum distance of each of the first light-emitting devices and the substrate is greater than a minimum distance of each of the second light-emitting devices and the substrate.

2. The light-emitting apparatus of claim 1, wherein the adhesive layer further has a plurality of second adhesive bumps, a height of each of the first adhesive bumps is greater than a height of each of the second adhesive bumps, at least a portion of the second adhesive bumps is interspersed between the first adhesive bumps, and the second light-emitting devices are respectively disposed on the second adhesive bumps of the adhesive layer.

3. The light-emitting apparatus of claim 2, wherein the adhesive layer further has a plurality of third adhesive bumps, and the height of each of the second adhesive bumps is greater than a height of each of the third adhesive bumps, wherein one of the third adhesive bumps is located between one of the first adhesive bumps and one of the second adhesive bumps adjacent to each other, and the light-emitting apparatus further comprises:
a plurality of third light-emitting devices respectively disposed on the third adhesive bumps of the adhesive layer.

4. The light-emitting apparatus of claim 3, wherein a thickness of each of the third light-emitting devices is greater than a thickness of each of the second light-emitting devices, and the thickness of each of the second light-emitting devices is greater than a thickness of each of the first light-emitting devices.
